(19) United States
(12) Patent Application Publication
(10) Pub. No.: US 2020/0303596 A1
(43) Pub. Date: Sep. 24, 2020

(54) LIGHT-EMITTING DEVICE PACKAGE AND LIGHTING MODULE

(71) Applicant: LG INNOTEK CO., LTD., Seoul (KR)

(72) Inventors: Chang Man LIM, Seoul (KR); June O SONG, Seoul (KR); Won Jung KIM, Seoul (KR); Hyoung Jin KIM, Seoul (KR); Hwan Hee JEONG, Seoul (KR)

(73) Assignee: LG INNOTEK CO., LTD., Seoul (KR)

(21) Appl. No.: 16/649,452

(22) PCT Filed: Sep. 21, 2018
(86) PCT No.: PCT/KR2018/011216

§ 371 Date: Mar. 20, 2020

(30) Foreign Application Priority Data
Sep. 22, 2017 (KR) 10-2017-0122869
Oct. 20, 2017 (KR) 10-2017-0136896

(51) Int. Cl. H01L 33/48; H01L 33/10; H01L 33/20; H01L 33/38; H01L 33/62; H01L 23/00

(52) U.S. Cl. CPC H01L 33/486; H01L 33/10; H01L 33/20; H01L 2933/0033; H01L 33/62; H01L 24/48; H01L 2224/48091; H01L 33/38

(57) ABSTRACT

The light-emitting device package disclosed in the embodiment includes first and second frames; a body supporting the first and second frames; and a light emitting device on the second frame, and the body may include a lower surface, a first side, and a second side facing the first side. The first frame includes a first recess that is concave in a second side direction from a first side portion adjacent to the first side, and the second frame includes a second recess that is concave in a first side direction from a second side portion adjacent to the second side. The first side portion of the first frame includes plurality of protrusions exposed to the first side of the body, the first recess is disposed between the protrusions of the first side portion, the second side portion of the second frame includes plurality of protrusions exposed to the second side of the body, and the second recess is disposed between the protrusions of the second side portion. A first length in the second direction of the first and second recesses is longer than a width in the first direction, and the first length may be larger than the second length in the second direction, which is an interval between the protrusions disposed in each of the first and second frames.

### TECHNICAL FIELD

An embodiment relates to a light emitting device package, a semiconductor device package, a method of manufacturing the semiconductor device package, a lighting module, or a light source device.

### BACKGROUND ART

A light emitting device may serve as a p-n junction diode having a characteristic of converting electric energy into light energy by using group III-V or II-VI elements of the periodic table, and may provide various wavelengths by controlling the composition ratio of compound semiconductors.

For instance, a nitride semiconductor represents superior thermal stability and wide band gap energy so that the nitride semiconductor has been spotlighted in the field of optical devices and high-power electronic devices. In particular, blue, green, and UV light emitting devices employing the nitride semiconductor have already been commercialized and extensively used.

For example, an ultraviolet light emitting device may be used as a light emitting diode that emits light distributed in a wavelength range of 200 nm to 400 nm, used for sterilization and purification in the case of a short wavelength in the wavelength band, and used for an exposure machine, a curing machine, or the like in the case of a long wavelength.

In addition, in the light emitting device package, studies on a method for reducing the manufacturing cost and improving the manufacturing yield by improving the process efficiency and changing the structure have been performed.

### DISCLOSURE

### Technical Problem

An embodiment of the present invention provides a light emitting device package and a method of manufacturing the same in which a lower portion of both sides of the body has recesses recessed in a direction of an upper surface of the body.

An embodiment of the present invention provides a light emitting device package having a recessed recess in a direction of the upper surface of the body on a lower portion of the outer side of each of the frames and a method of manufacturing the same.

An embodiment of the present invention provides a light emitting device package having a structure for enhancing the rigidity of the body disposed between the frames and a method of manufacturing the same.

An embodiment of the present invention provides a light emitting device package having a protrusion structure protruding toward the light emitting device from the upper portion of the body disposed between the frames and a method of manufacturing the same.

An embodiment of the present invention provides a light emitting device package having a protrusion protruding toward a center of the body on the side surface of the cavity and a method of manufacturing the same.

An embodiment of the present invention provides a light emitting device package and a method of manufacturing the same, the body portion protruding in the lateral direction of the light emitting device.

An embodiment of the present invention may provide a light emitting device package and a lighting module that may improve light extraction efficiency and electrical characteristics.

### Technical Solution

A light emitting device package according to the embodiment may comprise: first and second frames spaced apart from each other; a body supporting the first and second frames; and a light emitting device disposed on the second frame, wherein the body includes a lower surface, a first side surface, and a second side surface facing the first side surface, wherein the first frame includes a first recess recessed in a direction of the second side surface from a first side portion adjacent to the first side surface, wherein the second frame includes a second recess recessed in a direction of the first side surface from a second side portion adjacent to the second side surface, wherein the first side portion of the first frame includes a plurality of protrusions exposed to the first side surface of the body, the first recess is disposed between the protrusions of the first side portion, wherein the second side portion of the second frame includes a plurality of protrusions exposed to the second side surface of the body, wherein the second recess is disposed between the protrusions of the second side portion, and a first length of a second direction of the first and second recesses is longer than a width of a first direction, wherein the first length is greater than a second length in a second direction, which is an interval between the protrusions disposed in each of the first and second frames, and wherein a ratio of the second length to the first length may be a range 0.3 to 0.6.

According to an embodiment of the present invention, a width in the second direction of the region where the first and second recesses and the protrusion overlap in the first direction in each protrusion may have a range of 0.5 to 1 compared to the second length.

According to an embodiment of the present invention, a portion of the body is exposed on the first and second recesses, and widths in the second direction of the first and second recesses may be wider than an interval between two protrusions of the first and second frames.

According to an embodiment of the present invention, the first and second recesses may have a width in the second direction greater than a width in the first direction perpendicular to the second direction.

According to an embodiment of the present invention, a portion having a minimum width that is coupled to the body in two protrusions protruding from the first and second frames corresponds to the first and second recesses in the second direction, and may be smaller than an outer width of each of the protrusions.

According to an embodiment of the present disclosure, the two protrusions of the first frame have a stepped portion around an upper portion of the first recess, and the two protrusions of the second frame may have a stepped portion around an upper portion of the second recess.

According to an embodiment of the present invention, the first and second frames are conductive frames, and the light emitting device may be disposed as one of a vertical chip, a horizontal chip, and a flip chip on the first and second frames.

According to an embodiment of the present invention, the body disposed between the first and second frames may be disposed under the light emitting device, and may have a recess or an opening.

According to an embodiment of the present invention, a reflective resin may be disposed in the recess or the opening.

A lighting module according to an embodiment of the present invention, a circuit board; the light emitting device package may be included on the circuit board.

A light emitting device package according to the embodiment of the present invention, first and second frames spaced apart from each other in a first direction; a body disposed between the first and second frames; a reflective portion disposed on the body and constituting a cavity; and a light emitting device disposed in the cavity and including a first and second bonding portions thereunder, wherein the body is spaced apart in a second direction perpendicular to the first direction, and includes a protrusion disposed on the body. The protrusion may contact the first and second frames and the reflective portion and be spaced apart in the second direction of the light emitting device, and the protrusion and the body may include a resin material.

According to an embodiment of the present invention, the light emitting device may include two side surfaces facing in the second direction, and the protrusion may be disposed to face the two side surfaces.

According to an embodiment of the present invention, the protrusion may have a height equal to or lower than a height of the reflective portion and protrude from an inner surface of the cavity toward the light emitting device.

According to an embodiment of the present invention, the protrusion, the reflective portion, and the body may be formed of the same material.

According to an embodiment of the invention, an upper surface of the protrusion may be formed of a flat surface.

According to an embodiment of the present invention, a distance between the protrusions and the light emitting device may gradually increase as the protrusions move away from the light emitting device.

According to an embodiment of the present invention, a bottom width of the protrusion may be greater than 1 times and less than 3 times the width of the first direction of the body in the first direction.

According to an embodiment of the invention, comprising a first resin disposed between the body and the light emitting device; and a recess disposed in the body and at least partially overlapping the light emitting device in a vertical direction.

According to an embodiment of the present invention, comprising a first through hole disposed in the first frame and a second through hole in the second frame, and the first and second through holes overlap with the light emitting device in the vertical direction. The first through hole is disposed under the first bonding portion of the light emitting device, the second through hole is disposed under the second bonding portion of the light emitting device, and the first and second through holes may include a conductive layer therein.

According to an embodiment of the present disclosure, a portion of the recess may protrude further outward than a second side surface of the light emitting device.

According to an embodiment of the present invention, a minimum distance between the recess and the protrusion may be smaller than a distance between the light emitting device and the protrusion.

A light source device having the light emitting device package may be provided.

### Advantageous Effects

According to an embodiment, by disposing recesses from each frame on both lower sides of the package body, an injection process of the body may be improved.

According to the embodiment, by providing a moisture penetration path long, it is possible to provide a moisture resistant or moisture resistant package.

According to the embodiment, a rigidity of the center region of the package may be enhanced.

According to an embodiment, it is possible to enhance the rigidity of the body disposed between the frames.

According to the embodiment, there is an advantage to improve light extraction efficiency, electrical characteristics and reliability.

According to the embodiment, there is an advantage to improve the process efficiency and to propose a new package structure to reduce a manufacturing cost and improve the manufacturing yield.

The semiconductor device package according to the embodiment may provide a body having a high reflectance, thereby preventing the reflective portion from being discolored, thereby improving the reliability of the semiconductor device package.

According to the semiconductor device package and the method of manufacturing the semiconductor device according to the embodiment, a re-melting phenomenon may be prevented from occurring in the bonding region of the semiconductor device package while the semiconductor device package is re-bonded to the substrate or the like.

### DESCRIPTION OF DRAWINGS

FIG. 1 is a perspective view of a light emitting device package according to a first embodiment of the present invention.

FIG. 2 is a plan view of the light emitting device package of FIG. 1.

FIG. 3 is a bottom view of the light emitting device package of FIG. 1.

FIG. 4 is a cross-sectional view taken along line A-A side of the light emitting device package shown in FIG. 2.

FIG. 5 is a cross-sectional view taken along line B-B side of the light emitting device package shown in FIG. 2.

FIG. 6 is a first modified example of the light emitting device package of FIG. 4.

FIG. 7 is a second modified example of the light emitting device package of FIG. 4.

FIG. 8 is a third modified example of the light emitting device package of FIG. 4.

FIG. 9 is a fourth modified example of the light emitting device package of FIG. 4.

FIGS. 10 to 13 are views for explaining the manufacturing process of the light emitting device package of FIG. 2.

FIG. 14 is an example of a lighting module having the light emitting device package of FIG. 4.

FIG. 15 is a plan view of a light emitting device package according to a second embodiment of the present invention.

FIG. 16 is a sectional view taken along line B1-B1 side of the light emitting device package of FIG. 15.

FIG. 17 is a cross-sectional view taken along line C-C side of the light emitting device package of FIG. 15.

FIG. 18 is a cross-sectional view taken along line D-D side of the light emitting device package of FIG. 15.

FIG. 19 is another example of the protrusion in the light emitting device package of FIG. 18.

FIG. 20 is an example in which a recess is disposed in a body of the light emitting device package of FIG. 15.

FIG. 21 is a cross-sectional view taken along line E-E side of the light emitting device package of FIG. 20.

FIG. 22 is a first modified example of the light emitting device package of FIG. 21.

FIG. 23 is a second modified example of the light emitting device package of FIG. 21.

FIG. 24 is another example of the protrusions of the light emitting device package of FIG. 20.

FIG. 25 is a cross-sectional view taken along line G-G side of the light emitting device package of FIG. 24.

FIG. 26 is another example of the protrusion of the light emitting device package of FIG. 15.

FIG. 27 is a cross-sectional view taken along line H-H side of the light emitting device package of FIG. 26.

FIG. 28 is another example of the protrusion of the light emitting device package of FIG. 27.

FIG. 29 is a third modified example of the light emitting device package of FIG. 21.

FIG. 30 is a fourth modified example of the light emitting device package of FIG. 21.

FIG. 31 is another example of the light emitting device package of FIG. 15.

FIG. 32 is an example of a light source device or module having a light emitting device package according to an embodiment of the present invention.

FIG. 33 is a cross-sectional view illustrating an example of a light emitting device applied to a light emitting device package according to an embodiment of the present invention.

### BEST MODE

Hereinafter, an embodiment will be described with reference to accompanying drawings. In the description of the embodiments, it will be understood that, when a layer (or film), a region, a pattern, or a structure is referred to as being “on” or “under” another substrate, another layer (or film), another region, another pad, or another pattern, it may be “directly” or “indirectly” over the other substrate, layer (or film), region, pad, or pattern, or one or more intervening layers may also be present. Such a position of the layer has been described with reference to the drawings, but the embodiments are not limited thereto.

Hereinafter, a semiconductor device package according to an embodiment will be described in detail with reference to accompanying drawings. The semiconductor device of the device package may include a light emitting device emitting light such as ultraviolet, infrared, or visible light. Hereinafter, as an example of a semiconductor device, a case where a light emitting device is applied will be described, and a package or a light source unit to which the light emitting device is applied may include a non-light emitting device such as a Zener diode or a sensing device for monitoring a wavelength or heat. Hereinafter, as an example of a semiconductor device, a case where a light emitting device is applied will be described, and a light emitting device package will be described in detail.

### First Embodiment

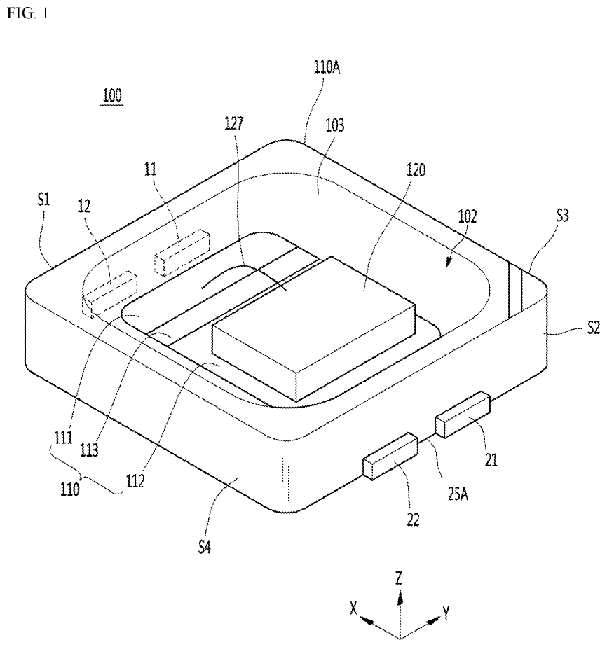

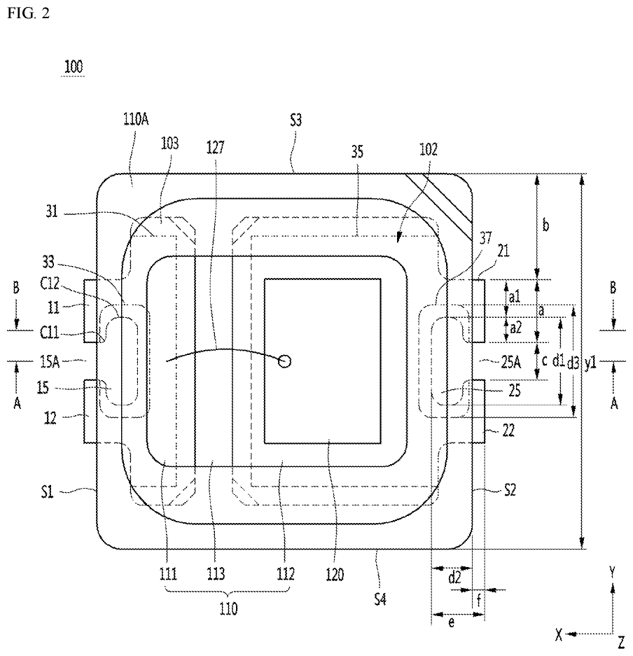

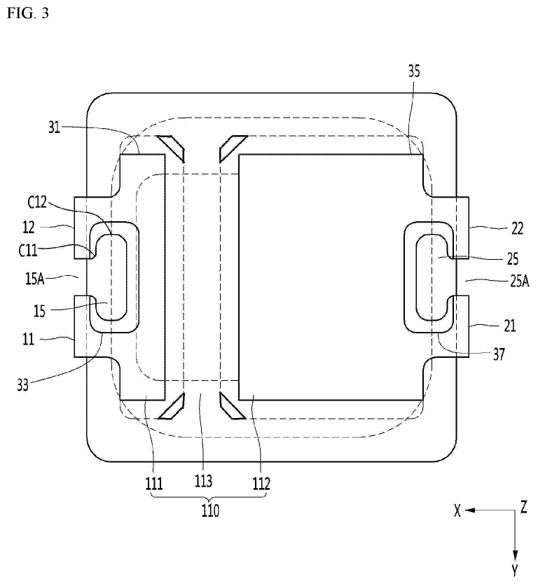

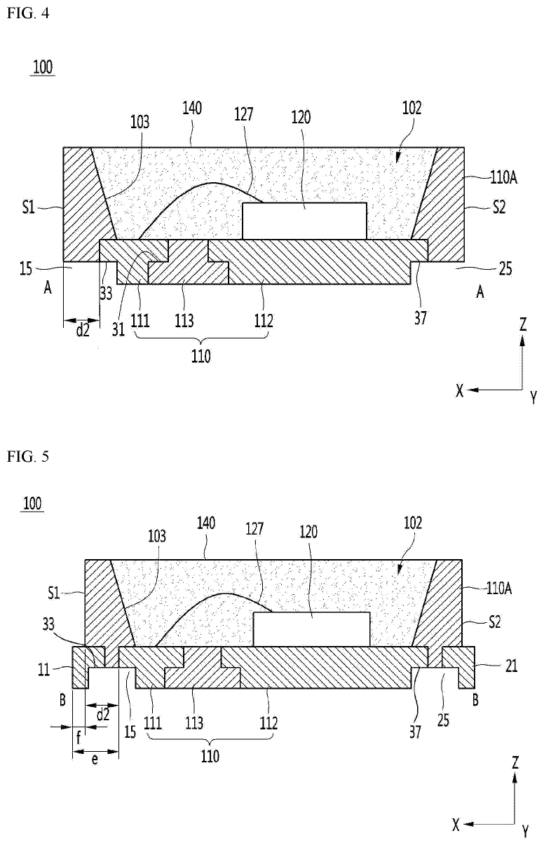

FIG. 1 is a perspective view of a light emitting device package according to a first embodiment of the present invention, FIG. 2 is a plan view of the light emitting device package of FIG. 1, FIG. 3 is a bottom view of the light emitting device package of FIG. 1, FIG. 4 is a cross-sectional view taken along line A-A side of the light emitting device package shown in FIG. 2, and FIG. 5 is a cross-sectional view taken along line B-B side of the light emitting device package shown in FIG. 2.

Referring to FIGS. 1 to 5, the light emitting device package 100 according to the embodiment may include a package body 110 and a light emitting device 120 disposed on the package body 110.

The package body 110 may include a plurality of frames, for example, a first frame 111 and a second frame 112. The first frame 111 and the second frame 112 may be spaced apart from each other in the first direction X. The package body 110 may have a length in the first direction X being the same as the length in the second direction Y or longer than the length in the first direction. The first direction is an X direction, the second direction is a Y direction orthogonal to the X direction, and the third direction is a direction orthogonal to the X and Y directions, and may be a vertical direction or a height or thickness direction.

The package body 110 may include a body 113. The body 113 may be disposed between the first frame 111 and the second frame 112. The body 113 may perform a function of a kind of electrode separation line. The body 113 may be referred to as an insulating member.

A portion of the body 113 may be disposed on the first and second frames 111 and 112. The body 113 may provide an inclined surface disposed on the first frame 111 and the second frame 112. The cavity 102 may be provided on the first frame 111 and the second frame 112 by the inner surface 103 of the body 113. The package body 110 may provide a reflective portion 110A having the cavity 102. The reflective portion 110A may cover a periphery of the cavity 102 and be coupled to the body 110. The inner surface 103 may be provided as a surface inclined with respect to the bottom of the package body 110, but may be a vertical surface or a curved surface as another example. In another example, the package body 110 may be provided in a structure having a flat top surface without the cavity 102.

For example, the body 113 may be formed of at least one select the group consisting of Polyphthalamide (PPA), Polychloro triphenyl (PCT), liquid crystal polymer (LCP), Polyamide 9T (PA9T), silicon, epoxy molding compound (EMC), silicon molding compound (SMC), ceramic, photosensitive glass (PSG), sapphire (Al₂O₃) and the like. In addition, the body 113 may include high refractive fillers such as TiO₂ and SiO₂. The reflective portion 110A may be made of the same material as the body 113. As another example, the reflective portion 110A may be made of a material different from that of the body 113.

The reflective portion 110A or the body 113 includes first and second side surfaces S1 and S2 opposite to each other, third and fourth side surface opposite to each other and extends to a direction of the second side surface S2 at both ends of the first side surface S1. The first and second side surfaces S1 and S2 are disposed in the first direction and have a long length in the second direction, and the third and fourth side surfaces S3 and S4 are disposed in the second direction and may have a long length in the first direction.

The first frame 111 and the second frame 112 may be provided as a conductive frame or a lead frame. The first frame 111 and the second frame 112 may stably provide structural strength of the package body 110, and may be electrically connected to the light emitting device 120. The first protrusion of the first frame 111 may extend and be exposed or protrude in a direction of an outer side of the package body 110. The second protrusion of the second frame 112 may extend and be exposed or protrude in the direction of the outer side of the package body 110. The first frame 111 and the second frame 112 may include a hole structure or a recess structure coupled to the body 113 or/and the reflective portion 110A, but is not limited thereto. As another example, the first frame 111 and the second frame 112 may be provided as an insulating frame.

The first frame 111 and the second frame 112 may include a base layer and a barrier layer. The base layer may include a Cu layer. The barrier layer may be formed of at least one layer on the base layer, and may include, for example, at least one of a Ni layer and an Ag layer. The barrier layer may be a plating layer. The Ni layer has a small change in thermal expansion. When the barrier layer is the Ni layer, even if the package body is changed by thermal expansion, a position of the light emitting device may be stably fixed by the Ni layer. When the barrier layer is the Ag layer, the Ag layer may efficiently reflect light emitted from the light emitting device and improve luminous intensity.

According to an embodiment, the light emitting device 120 may include a Group II-VI and/or Group III-V compound semiconductor layer. For example, the semiconductor layer may include at least two elements selected from aluminum (Al), gallium (Ga), indium (In), phosphorus (P), arsenic (As), and nitrogen (N). The light emitting device 120 may emit at least one of ultraviolet light, blue light, green light, red light, or infrared light, but is not limited thereto.

The light emitting device 120 may be any one of a vertical chip or a flip chip or a horizontal chip. One or more light emitting devices 120 may be disposed in the cavity 102. When the plurality of light emitting devices 120 are disposed, the light emitting devices 120 may be disposed on the first frame 111 or the second frame 112. When the light emitting device 120 is disposed on the second frame 112, an area of an upper surface of the second frame 112 may be larger than an area of an upper surface of the first frame 111.

Referring to FIGS. 4 and 5, a molding member 140 may be disposed in the cavity 102, and the molding member 140 may include an insulating material. The molding member 140 may include wavelength conversion means for receiving the light emitted from the light emitting device 120 and providing the wavelength-converted light. For example, the molding member 140 may be at least one selected from the group including phosphors, quantum dots, and the like. The phosphor or quantum dot may emit light of blue, green, and red. The molding member 140 may not be formed. The molding member 140 may be formed in a single layer or a multilayer, and in the case of the multilayer, any one layer may be free of impurities such as phosphors, and the other layer may have impurities such as phosphors. A translucent moisture proof layer may be disposed on the surfaces of the molding member 140 and the reflective portion 110A, but is not limited thereto.

In the light emitting device package 100 according to the embodiment, the first frame 111 may have a first step portion 31 and the second frame 112 may have a second step portion 35. Some regions of the first step portion 31 and the second step portion 35 may be disposed to face each other.

The first frame 111 may include a third step portion 33 in a region adjacent to the first side surface S1. The second frame 112 may include a fourth step portion 37 in a region adjacent to the second side surface S2. The third step portion 33 and the fourth step portion 47 may be disposed on opposite sides from each other with respect to the bottom of the first and second frames 111 and 112.

The first step portion 31 of the first frame 111 is disposed in a region corresponding with the body 113 disposed between the first and second frames 111 and 112, and may extend along a side of the second direction of the first fame 111. The first step portion 31 may have a stepped structure from the edge of the first frame 111 toward the center of the first frame 111. The second step portion 35 of the second frame 112 is disposed in a region corresponding with the body 113 disposed between the first and second frames 111 and 112, and may extend along a side of the second direction of the second frame 112. The second step portion 35 may have a stepped structure from the edge of the second frame 112 toward the center of the second frame 112.

An upper width of the body 113 disposed between the first and second frames 111 and 112 may be wider than a lower width. The first step portion 31 of the first frame 111 and the second step portion 35 of the second frame 112 may increase an adhesion area with the body 113 and the body 113 and may strengthen the coupling with the body 113. Therefore, the body 113 disposed between the first and second frames 111 and 112 may enhance the rigidity of the center portion of the light emitting device package.

The third step portion 33 of the first frame 111 overlaps with the reflective portion 110A in the third direction in the lower region of the first frame 111 and may be disposed on an adjacent region to the first side surface S1. The fourth step portion 37 of the second frame 112 overlaps the reflective portion 110A in the third direction in the lower region of the second frame 112 and is disposed on an adjacent region to the second side surface S2. The third step portion 33 and the fourth step portion 37 may be disposed on opposite sides with respect to the cavity 102. The third and fourth stepped portions 33 and 37 and the peripheral region thereof are regions in which a gate is disposed in an injection process of the body 113, and may provide a stepped structure to closely contact the gate.

According to an embodiment of the present invention, when manufacturing a light emitting device package, regions for an injection gate may be disposed at a plurality of positions. When the region for the injection gate is plural, the body material may be injected through different gates. Accordingly, the injection efficiency of the body material may be improved and the molding of the body may be facilitated. By forming a body through the plurality of gates, the molding process of the body may be simplified. By filling the entire region of the body with a uniform pressure through the plurality of gates, the cured body surface may be uniform, so that the luminous flux may be improved.

Referring to FIGS. 2 and 3, the first frame 111 includes a plurality of protrusions protruding in the direction of the first side surface S1 of the body 113, and may include, for example, first and second protrusions 11 and 12. The second frame 112 may include a plurality of protrusions protruding in the direction of the body 113 or the reflective portion 110A and the second side surface S2, and may include, for example, third and fourth protrusions 21 and 22. The first and second protrusions 11 and 12 may extend in the direction of the first side surface S1 in the bottom region of the cavity 102. End portions of the first and second protrusions 11 and 12 may protrude outward form the first side surface S1 through the first side surface S1. The third and fourth protrusions 21 and 22 may extend in the direction of the second side surface S2 in the bottom area of the cavity 102. End portions of the third and fourth protrusions 21 and 22 may protrude outward from the second side surface S2 through the second side surface S2.

The first and second protrusions 11 and 12 may be branched from the first frame 111. The first and second protrusions 11 and 12 may have a width ‘a’ of a portion exposed to the outside of the first side surface S1 greater than a width of a portion disposed inward of the first side surface S1. The outer width ‘a’ of the first and second protrusions 11 and 12 may be the length of the second direction Y. The third and fourth protrusions 21 and 22 may be branched from the second frame 112. The third and fourth protrusions 21 and 22 may have a width ‘a’ of a portion exposed to the outside of the second side surface S2 greater than a width of a portion disposed inward the second side surface S1. The outer width ‘a’ of the third and fourth protrusions 21 and 22 may be a length in the second direction. The outer width ‘a’ may be smaller than the length d1 of the first and second recesses 15 and 25 in the second direction. The outer width c may provide the first and second open regions 15A and 25A, which are the inlets of the first and second recesses 15 and 25, at a narrower interval c, and it may provide an injection path of the epoxy molding compound (EMC). The interval c is a spacing between the first and second protrusions 11 and 12 and a spacing between the third and fourth protrusions 21 and 22, and may be provided equal to or more than the particle size of the epoxy molding compound so that the epoxy molding compound may be injected. The interval c may range from 100 micrometers to 200 micrometers. The particle size of the epoxy molding compound may be, for example, in the range of 50 micrometers to 150 micrometers. The ratio of the interval c to the length d1 is in the range of 0.3 to 0.6, within which the range is possible to provide a passage of the epoxy molding compound through the interval c, there may prove the efficiency with which particle particles of the epoxy molding compound are injected into each body region by the length of the first and second recess 15 and 25. The outer width a of each of the first to fourth protrusions 11, 12, 21, and 22 may be greater than the interval c between the first and second protrusions 11 and 12, or the interval c (c<a) between the third and fourth protrusions 21 and 22. Since the outer width a of each of the first to fourth protrusions 11, 12, 21, and 22 is greater than the interval c, the bonding force at the outside of each of the frames 111 and 112 may be improved. The width a may be in the range of 100 micrometers or more, for example 100 to 600 micrometers. The interval c may be in the range of 350 micrometers or less, for example 50 to 350 micrometers or 50 micrometers to 200 micrometers. The ratio a/c may be 0.5 to 1.8, and when smaller than the range, the function and rigidity of each protrusion 11, 12, 21 and 22 may be degraded, and when larger than the range, the coupling force with the body may be reduced.

Here, the minimum width a1 of the portion of the first to fourth protrusions 11, 12, 21, and 22 that is coupled to the body 113 is smaller than the outer width a and may be more than 100 micrometer. When the minimum width a1 is smaller than the above range, the frames 111 and 112 may be bent or twisted due to pressure in the injection molding process. The portion having the minimum width a1 may correspond to the first and second recesses 15 and 25 in the second direction. The first to fourth protrusions 11, 12, 21, and 22 may protrude from the first and second side surfaces S1 and S2 to a predetermined length f, and the length f may be 150 micrometers, for example, in a range from 50 to 150 micrometers. Each of the protrusions 11, 12, 21, 22 may be exposed for the test function. The protruding length f of the protrusions 11, 12, 21, 22 may be provided as a process margin during cutting, and each protrusion 11, 12, 21, 22 may be protrude outward from each of the side surfaces S1 and S2, and the bonding force may be improved.

The first and third protrusions 11 and 21 may be spaced apart from the third side surface S3, and the second and fourth protrusions 12 and 22 may be spaced apart from the fourth side surface S4. The first to fourth protrusions 11, 12, 21, and 22 may have a distance b spaced apart from the third or fourth side surfaces S3 and S4 of the body. The spaced distance b may be greater than or equal to 0.5 mm or greater than the outer width a of each of the protrusions 11, 12, 21, and 22. That is, satisfies b>a, and the difference between b and a may be 0.1 mm or more. By the b>a, the body 113 or the reflective portion 110A may support the outer side of each of the protrusions 11, 12, 21, and 22, so that the protrusions 11, 12, 21, and 22 are covered.

The third step portion 33 may be provided around the first recess 15, and the fourth step portion 37 may be provided around the second recess 25. Accordingly, the area of the injection gate may be increased. The outer portions of the first to fourth protrusions 11, 12, 21, and 22 may have a stepped structure or may not have a stepped structure, but are not limited thereto.

The lower portion of the package body 110 may include recesses 15 and 25 in regions adjacent to the first and second side surfaces S1 and S2 opposite to each other. The first frame 111 may include a first side portion disposed on the first side surface S1. The first side portion may include a plurality of protrusions 11 and 12 and a first recess 15. The second frame 112 may include a second side portion disposed on the second side surface S2. The second side portion may include the plurality of protrusions 21 and 22 and the second recess 26. The first recess 15 may include the first recess 15 concave in the direction of the second side surface S2 from the first side portion. The second recess 25 may be concave in the direction of the first side surface S1 at the second side surface portion.

Here, each of the first frame 111 and the second frame 112 includes third and fourth side portions facing each other, and each of the third and fourth side portions may include the step portions 31 and 35.

The first recess 15 may be adjacent to the first side surface S1, and the second recess 15 may be adjacent to the second side surface S2. Each of the first and second recesses 15 and 25 may be spaced apart from the third and fourth side surfaces S3 and S4 by the same distance. The first recess 15 may be disposed below the center region of the first side surface S1, and the second recess 25 may be disposed below the center region of the second side surface S2.

The first recess 15 may be disposed outside the first direction of the first frame 111. The first recess 15 may be adjacent to the first side surface S1 of the body 113 and disposed between the first and second protrusions 11 and 12. The first recess 15 may overlap the body 113 in the third direction. A portion of the body 113 may be exposed to the first recess 15 through the first and second protrusions 11 and 12. The body 113 may be disposed along the side of the first frame 111 without protruding from the first recess 15 disposed in the region between the first and second protrusions 11 and 12. The bottom of the body 113 exposed on the first recess 15 may be rough or concave.

The first recess 15 may be connected to the first open region 15A opened in the first direction between the first and second protrusions 11 and 12 disposed outside the first side surface S1. The width or the interval c of the first open region 15A in the second direction may be smaller than the lengths d1 (d1>c) of the first recess 15 in the second direction. The length d1 is greater than or equal to two times the interval c, and is provided larger than the particle size of the epoxy molding compound, and is injected in the upper direction of the body and an injection efficiency of the molding compound injecting in the periphery direction of the cavity through the first recess 15 may improve.

The length d1 in the second direction of the first recess 15 may be wider than the widths d2 (d1>d2) in the first direction. When the width d2 of the first direction is increased, it may be difficult to secure a distance between the bottom of the cavity 102 and the first recess 15 and moisture may penetrate after injection molding. When the width d2 of the first direction is too small, it may not be possible to provide a space for the injection gate.

The second recess 25 may be disposed outside the first direction of the second frame 112, and the second recess 25 is adjacent to the second side surface S2 of the body 113 and may be disposed between the third and fourth protrusions 21 and 22. The second recess 25 may overlap the body 113 in the third direction. A portion of the body 113 may be exposed to the second recess 25 through the third and fourth protrusions 21 and 22. The body 113 does not protrude from the second recess 25 disposed in the second open region 25A between the third and fourth protrusions 21 and 22, and the body 113 may be disposed along the side surface of the second frame 112. The bottom of the body 113 exposed on the second recess 25 may be rough or concave.

The second recess 25 may be connected to the second open region 25A opened in the first direction between the third and fourth protrusions 21 and 22 disposed outside the second side surface S2. The width or the interval c of the second open region 25A in the second direction may be smaller than the length d1 (d1>c) of the second recess 25 in the second direction. The length d1 is greater than or equal to twice the interval c, and is provided larger than the particle size of the epoxy molding compound, and the injection efficiency of the molding compound injected in the upper direction of the body and a periphery direction of the cavity through the second recess 25 may improve.

The length d1 in the second direction of the second recess 25 may be wider than the widths d2 (d1>d2) in the first direction. When the width d2 of the first direction is increased, the distance between the bottom of the cavity 102 and the second recess 25 may be narrowed, so that moisture may penetrate after injection molding. When the width d2 of the first direction is too small, it may not be possible to provide a space for the injection gate. In the first and second recesses 15 and 25, the length d1 in the second direction may be 1.6 times or more, for example, 1.6 times to 2.2 times longer than the width d2 of the first direction. The width d2 of the first direction may be 0.5 mm or less, for example, in the range of 0.25 mm to 0.5 mm. The widths d1 and d2 of the first and second directions may be the widths of the regions excluding the stepped portions.

The first and second recesses 15 and 25 may be disposed not to overlap the bottom of the cavity 102 in the third direction. The outer width or the interval c adjacent to the first and second side surfaces S1 and S2 in the first and second recesses 15 and 25 may be narrower the inner width d1 adjacent to the cavity 102.

The length d1 of the first and second recesses 15 and 25 in the second direction may be greater than the interval c, and the difference between the length d1 and the interval c may be 2×a2. The length a2 may be a length in which the first to fourth protrusions 11, 12, 21, and 22 extend in the first and second open regions 15A and 25A. The length a2 is a length in the second direction and may be provided as a passage for injecting the epoxy molding compound. The length a2 may extend to the minimum width a2 on both sides of the second direction than the distance c. The ratio of the minimum width a2 to the interval c may range from 0.5 to 1. The minimum width a2 may be at least 80 micrometers, for example, in the range of 80 micrometers to 120 micrometers. When the minimum width a2 is smaller than the range, it may be difficult to secure the injection passage of the epoxy molding compound, and when it is larger than the range, the improvement of the molding injection efficiency may be insignificant. That is, the minimum width a2 may be equal to or larger than the particle size of the epoxy molding compound. That is, the minimum length a2 is a length extending from the protrusions 11, 12, 21, and 22 to both sides of the first and second recesses 15, 25 and may be obtained as ½ of d1-c. The minimum width a2 may be obtained as a-a1. The minimum width a2 may be a width of a region where the first and second recesses 15 and 25 and the protrusions 11, 12, 21, and 22 overlap each other in the first direction.

The width or depth of the third and fourth steps portions 33 and 37 in the first and second recesses 15 and 25 may be at least 80 micrometers, for example, in the range of 80 to 150 micrometers. The width or depth of the third and fourth stepped portions 33 and 37 may be formed within the range in consideration of the distance to the bottom of the cavity 102, or when the width or depth of the third and fourth stepped portions 33 and 37 is in the second direction different from the cavity 102, the width or depth of the third and fourth stepped portions 33 and 37 may be formed deeper than the depth of the first direction.

Referring to FIGS. 2 and 3, each of the first and second protrusions 11 and 12 and the third and fourth protrusions 21 and 22 may include a corner C11, and the corner C11 may be provided in a curved or curved shape having a curvature and may be contacted with each of the first and second recesses 15 and 25. Since the corners C11 are provided in the curved shape, the pressure transmitted during the injection of the epoxy molding compound may be dispersed or the injection efficiency may be improved.

The outer side surfaces of the first recess 15 and the second recess 25 may include a round portion C12 having a curve shape or curved shape that is convex in the second direction. The round portion C12 may be disposed at a boundary portion between the outer side of the first recess 15 and the second recess 25 and the inner side surfaces of the first to fourth protrusions 11, 12, 21, and 22, respectively. The round portion C12 may be formed in a curve shape or curved surface convex in the second direction. Since the round portion C12 is provided in a curve shape or curved shape, the pressure transmitted during the injection of the epoxy molding compound may be dispersed, and the protruding portions of the first to fourth protrusions 11, 12, 21, and 22 may prevent bending or boiling problems and may improve the injection efficiency of the epoxy molding compound.

The depth e from the first and second side surfaces S1 and S2 of the package body 110 to the ends of the first and second recesses 15 and 25 may be 250 micrometers or more, for example, in the range of 250 to 400 micrometers. when the depth e of the first and second recesses 15 and 25 exceeds the above range, the package size may be increased or the distance from the cavity bottom may be shortened, when it is smaller than the above range, the first and second recesses 15 and 25 may not be used as a gate region.

The first and second recesses 15 and 25 may be spaced apart in the first direction. The first recess 15 may be concavely disposed from the first side surface S1 of the body 113 to a direction of the second side surface or in a direction the second frame 112 on a lower portion of the first frame 111. The second recess 25 may be concavely disposed in the direction of the first side surface or in the direction of the first frame 111 from the second side surface S2 of the body 113 on the lower portion of the second frame 112.

The interval between the first and second recesses 15 and 25 may be spaced greater than the bottom width of the cavity 102 in the first direction. This is because when the interval between the first and second recesses 15 and 25 is narrower than the bottom width of the cavity 102, the region into which the liquid body material is injected is not uniformly distributed or the area of the frames 111 and 112 is decreased, and a securing a moisture proof path adjacent to the cavity 102 may be a difficult problem.

The height or thickness of the first and second recesses 15 and 25 may be in a range of 40% or more, for example, 40% to 60% of the thicknesses of the first frame 111 and the second frame 112. When the thickness of the first and second recesses 15 and 25 exceeds the range, the frame stiffness may be reduced. When the thickness of the first and second recesses 15 and 25 is smaller than the range, the implantation efficiency may decrease. The thickness of the first frame 111 and the second frame 112 may be 200 micrometers or more, for example, in the range of 200 to 350 micrometers.

Here, when the length of one side of the package body 110, for example, the length in the second direction of the first and second side surfaces S1 and S2 is y1, the y1 may range from 2 mm to 5 mm. This length y1 may vary depending on the size of the light emitting device 120 and the number of mounted light emitting devices.

Referring to FIGS. 4 and 5, a portion of the body 113 overlaps with the body 113 in a region between the first and second protrusions 11 and 12 and may be disposed between the first recess 15 and the first side surface recess S1.

A portion of the body 113 overlaps with the body 113 in a region between the third and fourth protrusions 21 and 22 and is disposed between the second recess 25 and the second side surface S2. Herein, when a portion of the body 113 may be disposed between the first and second protrusions 11 and 12 and between the third and fourth protrusions 21 and 22, the portion of the body 113 may protrude in a stepped structure with respect to a bottom of the body 113.

The light emitting device 120 may be disposed on the second frame 112. When the light emitting device 120 is a vertical chip, the light emitting device 120 may be electrically connected to the second frame 112 by a conductive layer. When the light emitting device 120 is a horizontal chip, the light emitting device 120 may be attached to the second frame 112 with a conductive or insulating adhesive. The light emitting device 120 may be connected to the first frame 111 by a wire 127. Alternatively, the light emitting device 120 may be connected to the first frame 111 and the second frame 112 by wires. The conductive layer may be bonded between the second frame 112 and a lower electrode of the light emitting device 120. The conductive layer may include one material selected from the group including Ag, Au, Pt, Sn, Cu, or an alloy thereof. The material constituting at least one of the second frame 112 and the lower electrode and the material of the conductive layer may be combined with a compound. The compound may include at least one of CuₓSn_{y}, AgₓSn_{y}, and AuₓSn_{y}, and x may satisfy the condition of 0<x<1, y=1−x, x>y. For example, the conductive layer may be formed using a conductive paste. The conductive paste may include a solder paste, a silver paste, or the like, and may include a multilayer or a single layer composed of a multilayer or an alloy composed of different materials. For example, the conductive layer may include an SAC (Sn—Ag—Cu) material.

A protection device may be disposed on at least one of the first frame 111 and the second frame 112. The protection device may electrically protect the light emitting device 120. The protection element may be implemented as a thyristor, a Zener diode, or a transient voltage suppression (TVS), and the Zener diode protects the light emitting device 120A from an electro static discharge (ESD).

The light emitting device package may be mounted on a sub-mount or a circuit board. However, in the conventional light emitting device package is mounted on a sub-mount or a circuit board, a high temperature process such as a reflow may be applied. At this time, in the reflow process, a re-melting phenomenon occurs in the bonding region between the lead frame and the light emitting device provided in the light emitting device package, thereby weakening the stability of the electrical connection and the physical coupling.

However, the first bonding portion 121 and the second bonding portion 122 of the light emitting device according to the embodiment may receive driving power through the frames 111 and 112 and the conductive layer. The melting point of the conductive layer may be selected to have a higher value than the melting point of other bonding materials. Accordingly, the light emitting device package according to the embodiment does not cause re-melting even when bonded to a main substrate through a reflow process, so that the electrical connection and physical bonding force may not degraded. In addition, according to the light emitting device package according to the embodiment, the package body 110 does not need to be exposed to high temperatures in the process of manufacturing the light emitting device package. Therefore, according to the embodiment, the package body 110 may be prevented from being damaged or discolored due to exposure to high temperature.

According to an embodiment, the first and second recesses 15 and 25 are disposed in opposite regions of the lower portion of the package body 110 or opposite regions of each of the frames 111 and 112, respectively, so that the light extraction efficiency may be improved.

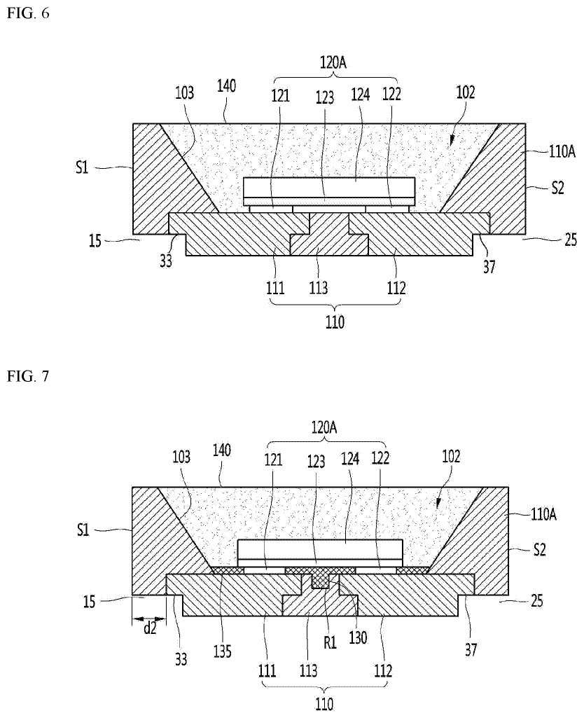

FIGS. 6 to 9 illustrate first to fourth modified examples of the light emitting device package of FIG. 4. Referring to FIGS. 6 to 9, the same parts as the above description will be referred to the above description and may be selectively applied.

Referring to FIG. 6, the light emitting device package may include a light emitting device 120A disposed on the package body 110. According to an embodiment, the light emitting device 120A may include a first bonding portion 121, a second bonding portion 122, a light emitting structure 123, and a substrate 124.

The substrate 124 is a light transmitting layer and may be formed of an insulating material or a semiconductor material. The substrate 124 may be selected from a group including, for example, sapphire substrate (Al₂O₃), SiC, GaAs, GaN, ZnO, Si, GaP, InP, and Ge. For example, an uneven pattern may be formed on a surface of the substrate 124. The substrate 124 may be removed or a light transmitting layer of another resin material may be disposed.

The light emitting structure 123 may include a first conductive semiconductor layer, a second conductive semiconductor layer, an active layer disposed between the first conductive semiconductor layer and the second conductive semiconductor layer. The first bonding portion 121 may be electrically connected to the first conductive semiconductor layer. In addition, the second bonding portion 122 may be electrically connected to the second conductive semiconductor layer. In addition, according to the embodiment, the light emitting structure 123 may be provided as a compound semiconductor. The light emitting structure 123 may be provided as, for example, a Group II-VI or Group III-V compound semiconductor. For example, the light emitting structure 123 may include at least two elements selected from aluminum (Al), gallium (Ga), indium (In), phosphorus (P), arsenic (As), and nitrogen (N). The first conductive semiconductor layer may be an n-type semiconductor layer doped with n-type dopants such as Si, Ge, Sn, Se, Te, or the like. The second conductive semiconductor layer may be a p-type semiconductor layer doped with p-type dopants such as Mg, Zn, Ca, Sr, and Ba.

The light emitting device 120A may include first and second bonding portions 121 and 122 at a lower portion thereof, and the first and second bonding portions 121 and 122 may be electrodes or pads. The first bonding portion 121 may be electrically connected to the first conductivity type semiconductor layer. The second bonding portion 122 may be electrically connected to the second conductive semiconductor layer. The first bonding portion 121 and the second bonding portion 122 may include at least one of a metal and a non-metal material. The first and second bonding portions 121 and 122 may be formed in a single layer or multiple layers using one or more materials or alloys of Ti, Al, In, Ir, Ta, Pd, Co, Cr, Mg, Zn, Ni, Si, Ge, Ag, Ag alloy, Au, Hf, Pt, Ru, Rh, ZnO, IrOx, RuOx, NiO, RuOx/ITO, Ni/IrOx/Au, Ni/IrOx/Au/ITO.

The light emitting device 120A may be disposed on the package body 110, the first frame 111, and the second frame 112. The light emitting device 120A may be disposed on the body 113. A conductive layer may be disposed between the first frame 111 and the first bonding portion 121 of the light emitting device 120A and between the second frame 112 and the second bonding portion 122 of the light emitting device 120A.

At least one or both of the first frame 111 and the second frame 112 may have an upper recess in which an upper portion is concave, and the upper recess may be a recessed region lower than the upper surface of the first frame 111 and the second frame 112. The upper recess may be filled with a resin material, for example, a white reflective resin, to reflect light, and the white reflective resin may be disposed between the molding member 140 and the frames 111 and 112. The white resin may be disposed lower than the lower surface of the light emitting device 120A, so that light reflection may be effectively performed.

FIG. 7 is a second modified example of the light emitting device package of FIG. 4.

Referring to FIG. 7, the light emitting device package may include an upper recess in at least one or both of upper portions of the frames 111 and 112 and upper portions of the body 113. A first upper recess R1 may be disposed the upper portion of the body 113. The first upper recess R1 may be disposed between the first frame 111 and the second frame 112. The first upper recess R1 may be recessed in a direction of a lower surface from an upper surface of the body 113. The first upper recess R1 may be disposed under the light emitting device 120A. The first upper recess R1 may be provided to overlap the light emitting device 120A in the third direction. The length of the first upper recess R1 in the second direction may be longer than that of the second light emitting device 120A.

The first resin 130 may be disposed in the first upper recess R1. The first resin 130 may be disposed between the light emitting device 120A and the body 113. The first resin 130 may contact the lower surface of the light emitting device 120A. A portion of the first resin 130 may be disposed in the first upper recess R1. A portion of the first resin 130 may be disposed between the light emitting device 120A and the body 113. A portion of the first resin 130 may be disposed between the first bonding portion 121 and the second bonding portion 122. For example, a portion of the first resin 130 may be in contact with a side surface of the first bonding portion 121 and a side surface of the second bonding portion 122.

The first resin 130 may be disposed in the first upper recess R1 to provide a stable fixing force between the light emitting device 120A and the body 113. For example, the first resin 130 may directly contact the upper surface of the body 113 and the lower surface of the light emitting device 120A. The first resin 130 may provide a light diffusing function between the light emitting device 120A and the body 113 and may improve light extraction efficiency. When the first resin 130 includes a reflection function, the first resin 130 may include at least one filler of TiO₂, Al₂O₃, and SiO₂.

In example embodiments, a depth of the first upper recess R1 may be smaller than a thickness of the frames 111 and 112. The depth of the first upper recess R1 may be determined in consideration of the adhesive force of the first resin 130. In addition, the depth of the first upper recess R1 may be determined by considering the stable strength of the body and/or by the heat emitted by the light emitting device 120A to prevent cracking of the light emitting device package.

The first upper recess R1 may provide a suitable space in which an underfill process due to the first resin 130 may be performed under the light emitting device 120A. Here, the underfill process may be a process of mounting the light emitting device 120A on the package body 110 and then disposing the first resin 130 under the light emitting device 120A, or a process in which the light emitting device 120A may be disposed after the first resin 130 may be disposed in the first upper recess R1. The first upper recess R1 may be provided beyond the first depth so that the first resin 130 is sufficiently provided. In addition, the first upper recess R1 may be provided below a second depth in order to provide stable strength of the body 113. The depth of the first upper recess R1 may be provided at 100 micrometers or less, for example, 15 micrometers to 100 micrometers.

A width in the first direction of the first upper recess R1 may be smaller than an interval between the frames 111 and 112. The width of the first upper recess R1 may be provided in the long axis direction of the light emitting device 120A. For example, the width of the first upper recess R1 may be provided to 140 micrometers to 160 micrometers. The length of the first upper recess R1 in the second direction may be longer than that of the light emitting device 120A, and in this case, the first resin 130 may be exposed outside the light emitting device 120A to perform the light reflection function. The length of the first upper recess R1 in the second direction may be smaller than the length of the long axis direction of the light emitting device 120A. In this case, the first resin 130 may be adhered to the lower surface of the light emitting device 120A and may be function as an adhesive agent and a reflective member. The length of the first upper recess R1 in the second direction may be disposed in the open region of the first resin 130 or may be in contact with the first resin 130.

The second resin 135 may be disposed between the frames 111 and 112 and the light emitting device 120A. The upper surface of the second resin 135 may be disposed at a height lower than the upper surface of the light emitting device 120A or lower than the lower surface of the active layer. The second resin 135 may be in contact with the molding member 140. When the light is emitted in the lateral direction of the light emitting device 120A, the second resin 135 may reflect light to improve light extraction efficiency. The second resin 135 may reflect light emitted from the light emitting device 120A. When the second resin 135 includes a reflection function, the second resin 135 may include at least one filler of TiO₂, Al₂O₃, and SiO₂.

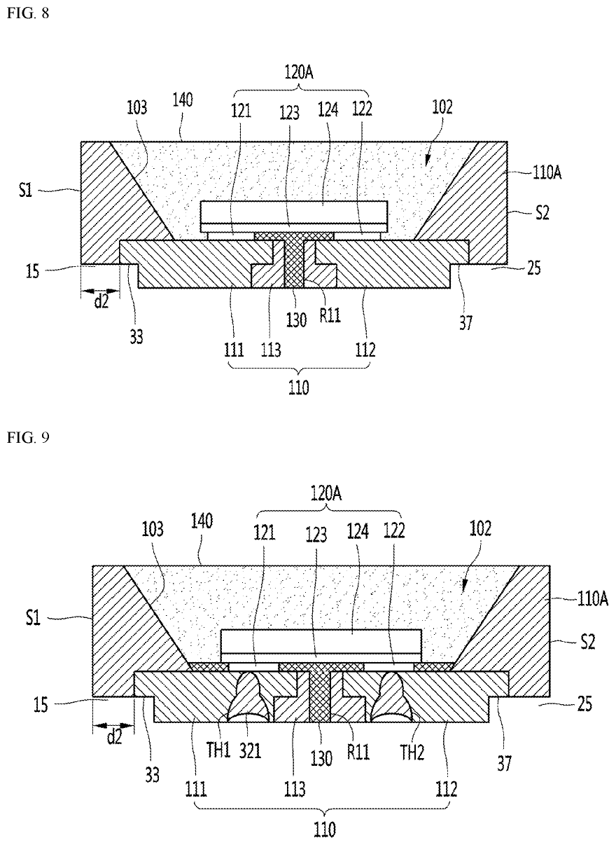

Referring to FIG. 8, the light emitting device package may include an opening in at least one or both of the frames 111 and 112 and the body 113. The opening R11 may be provided, for example, in the body 113. The opening R11 may be provided at the same height as the thicknesses of the first and second frames 111 and 112. The opening R11 may be disposed in the body 113 disposed between the first and second frames 111 and 112 and may penetrate from the upper surface of the body 113 to the lower surface. The opening R11 may be disposed under the light emitting device 120A. The thickness of the body 113 disposed outside the opening R11 may have the same thickness as that of the first frame 111 and the second frame 112.

The first resin 130 may be filled in the opening R11, and a lower projection of the first resin 130 may be formed in the opening R11. The lower projection may be exposed to the lower portion of the body 113. The material of the first resin 130 will be referred to the description above. The first resin 130 may enhance the lower adhesive force and the support force of the light emitting device 120A. The first resin 130 may perform a heat dissipation function through the lower projection. The first resin 130 may include at least one filler of TiO₂, Al₂O₃, and SiO₂ therein, and thermal conductivity may be improved. When the first resin 130 is formed, a support sheet may be disposed on the lower portion and then formed on the opening R11. In this package, as shown in FIG. 7, a second resin may be disposed.

In FIGS. 7 and 8, concave recesses may be disposed in the first frame 111 and the second frame 112 on which the second resin is disposed, and a portion of the second resin may be disposed.

Referring to FIG. 9, through holes TH1 and TH2 may be disposed in at least one or both of the frames of the light emitting device package. The through holes TH1 and TH2 may include a first through hole TH1 disposed in the first frame 111 and a second through hole TH2 disposed in the second frame 112. The first and second through holes TH1 and TH2 may be holes penetrating from upper surfaces to lower surfaces of the first and second frames 111 and 112. The first and second through holes TH1 and TH2 may be one or more in each of the frames 111 and 112.

Surfaces of the first and second through holes TH1 and TH2 may include at least one of a vertical surface, an inclined surface, or a curved surface. The surfaces of the first and second through holes TH1 and TH2 may include curved surfaces having different curvatures. A plating layer may be formed on the surfaces of the first and second through holes TH1 and TH2 to protect the frame.

The first and second through holes TH1 and TH2 may overlap the light emitting device 120A in the third direction. The first through hole TH1 may overlap the first bonding portion 121 of the light emitting device 120A in the third direction. The second through hole TH2 may overlap the second bonding portion 122 of the light emitting device 120A in the third direction. The first and second through holes TH1 and TH2 may have an upper width or diameter smaller than a lower width or diameter.

A conductive layer 321 may be formed in the first and second through holes TH1 and TH2. The conductive layer 321 disposed in the first through hole TH1 may be in direct contact with the bottom surface of the first bonding portion 121 and may be electrically connected to the first bonding portion 121. The first frame 111 may be disposed around the conductive layer 321. The conductive layer 321 disposed in the second through hole TH2 may be disposed under the second bonding portion 122. The conductive layer 321 disposed in the second through hole TH2 may be in direct contact with the lower surface of the second bonding portion 122 and may be electrically connected to the second bonding portion 122. The conductive layer 321 may include one material selected from the group consisting of Ag, Au, Pt, Sn, Cu, Zn, In, Bi, Ti, or an alloy thereof. The conductive layer 321 may be a material capable of securing a conductive function. The conductive layer 321 is a solder paste, and may be formed by mixing powder particles or particle particles with flux. The solder paste may include Sn—Ag—Cu or SAC-based materials, and a weight percentage of each metal may vary.

For example, the conductive layer 321 may be formed using a conductive paste. The conductive paste may include a solder paste, a silver paste, or the like, and may include a multilayer or a single layer composed of a multilayer or an alloy composed of different materials.

Recess R11 disposed in a region between the first frame 111 and the second frame 112 will be described with reference to the description of FIG. 8, and is formed of the recess shown in FIG. 7, but it is not limited thereto.

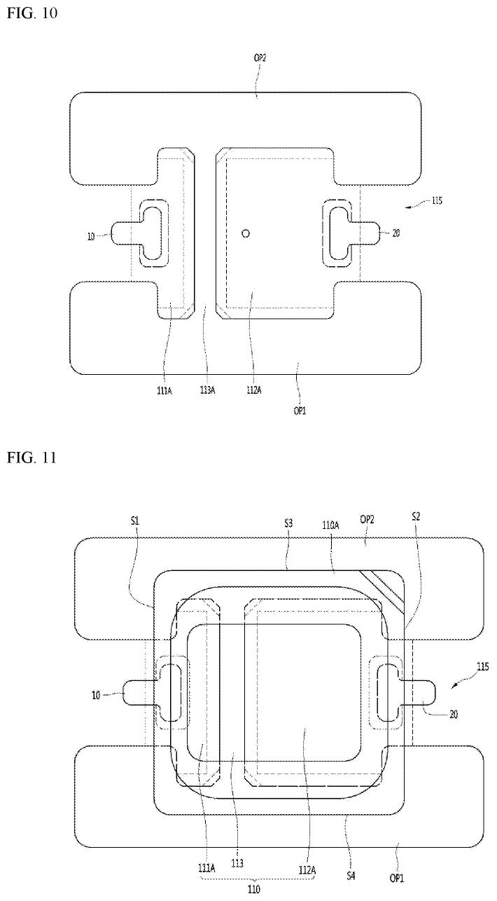

FIGS. 10 to 13 are views illustrating a manufacturing process of a light emitting device package according to an embodiment.

As shown in FIG. 10, a frame plate 115 having a first frame portion 111A and a second frame portion 112A separated from each other is provided, and a separation region 113A between the first and second frame portions 111A and 112A and an open portions OP1 and OP2 connected thereto may be disposed. The open portions OP1 and OP2 may be connected to the separation region 113A.

A first gate region 10 may be disposed in the first frame portion 111A, and a second gate region 20 may be disposed in the second frame portion 112A. The first and second gate regions 10 and 20 may be open regions when an upper mold and a lower mold are combined for injection molding of the body.

Referring to FIGS. 10 and 11, gates may be coupled through the first and second gate regions 10 and 20, and a liquid body material may be injected. Accordingly, a reflective portion 110A having a body 113 and a cavity may be formed to be combined with the frame portions 111A and 112A. The first and second gate regions 10 and 20 may be disposed on opposite sides to improve the injection efficiency of the liquid material. That is, the first and second gate regions 10 and 20 may be disposed in the farthest region on a straight line connecting the centers of both sides of the body 113, so that the injection efficiency of the body due to the injection of the liquid is increased, and the injection efficiency of the body may be improved and the process may be simplified. In addition, the gate region is not disposed in the region between the first and second frame portions 111A and 112A, thereby preventing the center of the package body from being damaged when forming the body.

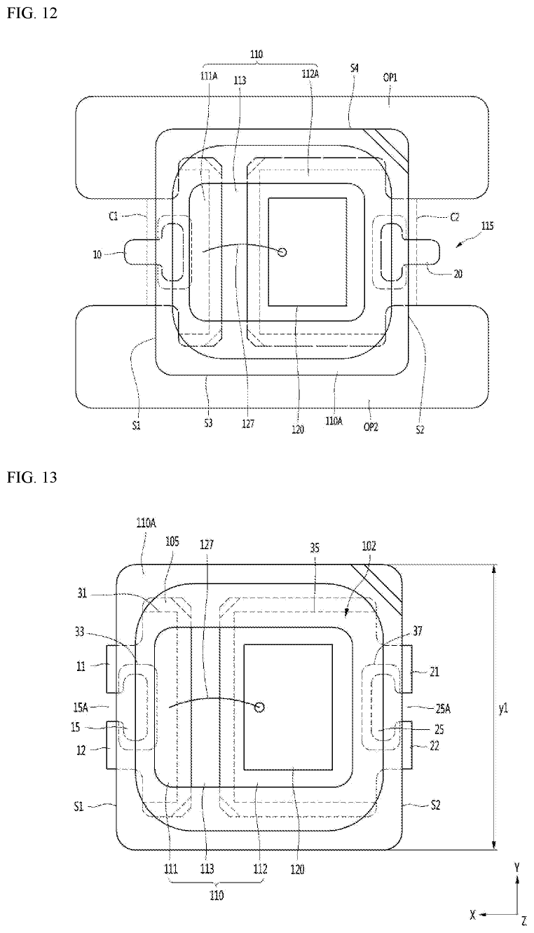

Referring to FIGS. 11 and 12, when the body 113 is molded, the light emitting device 120 is mounted on the second frame portion 112A as shown in FIG. 12, and the first frame portion 111 is connected to the wire 127. Thereafter, a molding member is formed in the upper cavity of the package body 110 through a dispensing process. The molding member may have a phosphor added therein, but is not limited thereto. The molding member may not be formed.

Referring to FIGS. 12 and 13, the frame plate 115 may be cut along the cutting lines C1 and C2 and provided as a unit light emitting device package as shown in FIG. 13. Protrusions 11, 12, 21, and 22 may be exposed on the first and second side surfaces S1 and S2 of the package body 110. First and second recesses 15 and 25 may be disposed in lower regions adjacent to the first and second side surfaces S1 and S2 of the package body 110, and the lower regions adjacent to the first and second side surfaces S1 and S2 of the package body 110 may be connected to the first and second open regions 15A and 25A opened by the protrusions 11, 12, 21, and 22. Thus, by injecting the liquid body material through the gate region disposed on the opposite side, it may be uniformly injected into the entire region, it can provide a uniform body surface and the adhesion force with the frames may be improved.

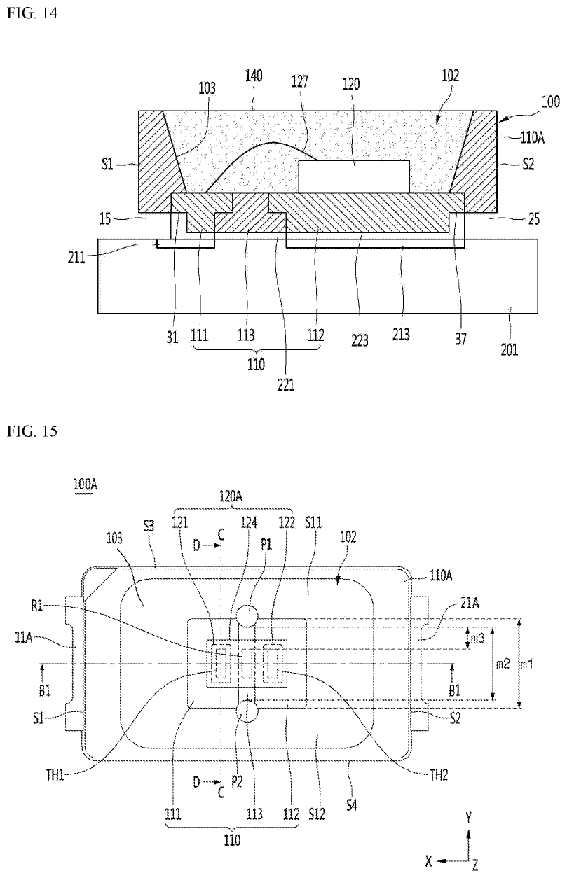

FIG. 14 is an example of a module having a light emitting device package according to an embodiment.

Referring to FIG. 14, in the lighting module, one or a plurality of light emitting device packages 100 may be disposed on the circuit board 201. The circuit board 201 may be provided with a power supply circuit for controlling the driving of the light emitting device 120.

The package body 110 may be disposed on the circuit board 201. The first frame 111 and the second frame 112 of the light emitting device package 100 may be electrically connected to the circuit board 201 by bonding layers 221 and 223 to pads 211 and 213 of the circuit board 201. The light emitting device package according to the embodiment does not have a re-melting phenomenon even when bonded to a circuit board through a reflow process, so that the electrical connection and physical bonding force are not degraded. Therefore, according to the embodiment, the package body 110 may be prevented from being damaged or discolored due to exposure to high temperature.

### Second Embodiment

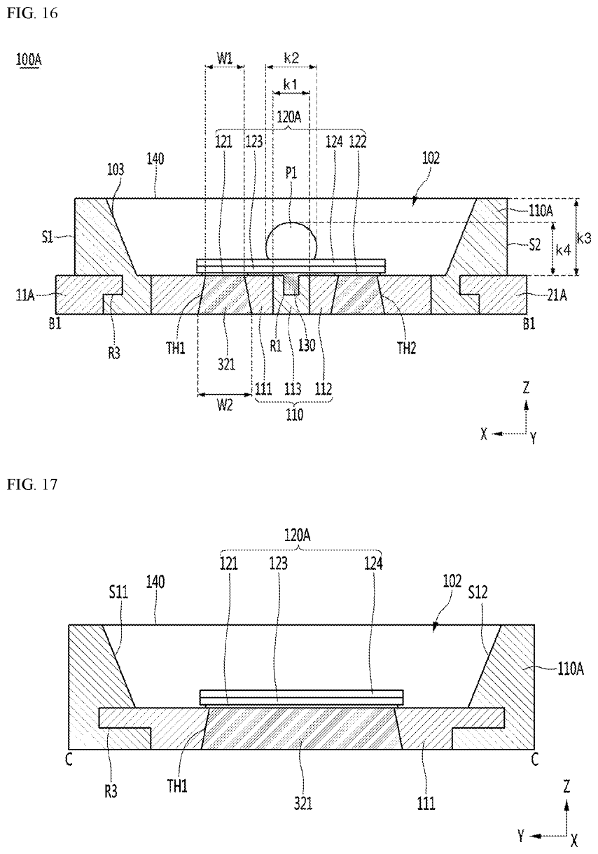

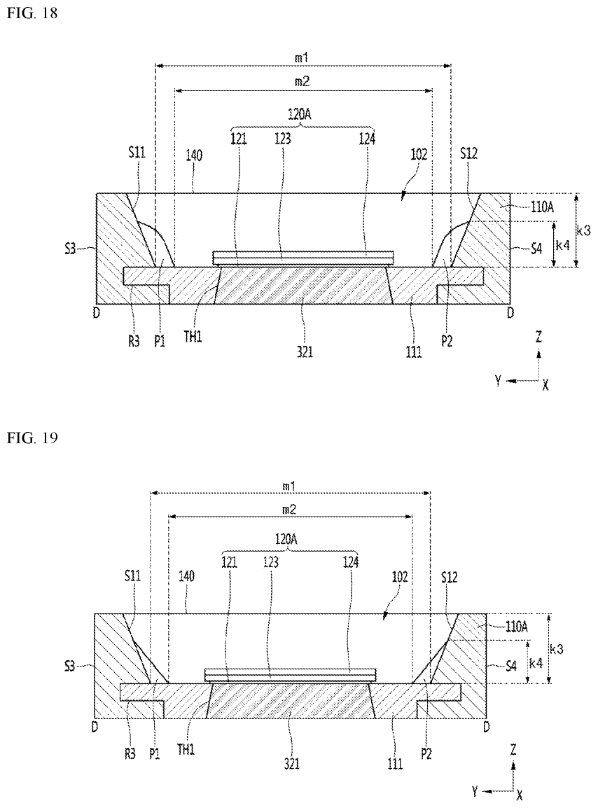

FIG. 15 is a plan view of a light emitting device package according to a second embodiment of the present invention, FIG. 16 is a sectional view taken along line B1-B1 side of the light emitting device package in FIG. 15, and FIG. 17 is a sectional view taken along line C-C side of the light emitting device package in FIG. 15, FIG. 18 is a cross-sectional view taken along line D-D side of the light emitting device package of FIG. 15, and FIG. 19 is another example of the projection of the light emitting device package of FIG. 18. The second embodiment refers to the description of the first embodiment for the same configuration as that of the first embodiment and may optionally include the configuration of the first embodiment.

Referring to FIGS. 15 to 19, in the light emitting device package 100A, a length of the first direction X of the package body 110 may be the same as the length of the second direction Y, or the length of the first direction may be longer than a length of the second direction. Here, the first direction may be a direction of a side having a longer length among the lengths of the first and second directions of the light emitting device 120A.

The first protrusion 11A of the first frame 111 may extend and protrude in the direction of the first side surface S1 of the package body 110. The second protrusion 21A of the second frame 112 may extend and protrude in the direction of the second side surface S2 of the package body 110. The first and second protrusions 11A and 21A may be arranged in one or plural. The first and second protrusions 11A and 21A may provide the same structure as the protrusion of the first embodiment.

The light emitting device 120A may include a first bonding portion 121, a second bonding portion 122, and a light emitting structure 123. The light emitting device 120A may include a substrate 124. The light emitting device 120A may have a length in the first direction equal to or longer than a length in the second direction. The first and second bonding portions 121 and 122 may be disposed under the light emitting structure 123. The first bonding portion 121 and the second bonding portion 122 may be spaced apart from each other on the lower surface of the light emitting device 120A. The first bonding portion 121 may be disposed on the first frame 111. The second bonding portion 122 may be disposed on the second frame 112. The description of the light emitting device 120A will be described with reference to FIGS. 6 to 9.

The light emitting device 120A may be disposed on the first frame 111, the second frame 112, and the body 113. The light emitting device 120A may be disposed in the cavity 102, and the reflective portion 110A may be disposed around the light emitting device 120A.

An inner surface 103 of the cavity 102 may be inclined with respect to the horizontal bottom of the body 113. The inner surface 103 of the cavity 102 can improve the directivity distribution and extraction efficiency of the light. The inner surface 103 of the cavity 102 may include a first inner side surface S11 and a second inner side surface S12 in a direction in which the body 113 disposed between the first and second frames 111 and 112 passes. The first inner side surface S11 and the second inner side surface S12 may face each other. The first inner side surface S11 and the second inner side surface S12 may be inclined with respect to the bottom of the package body 110 or the horizontal cavity bottom. The first inner side surface S11 corresponds to the third side surface S3 of the package body 110, and the second inner side surface S12 may correspond to the fourth side surface S4 of the package body 110.

In the light emitting device 120A, the first bonding portion 121 may be disposed between the light emitting structure 123 and the first frame 111. The second bonding portion 122 may be disposed between the light emitting structure 123 and the second frame 112. The first bonding portion 121 and the second bonding portion 122 may include a metal material.

The light emitting device 120A may include one or a plurality of light emitting cells therein. The light emitting cell may include at least one of an n-p junction, a p-n junction, an n-p-n junction, and a p-n-p junction. The plurality of light emitting cells may be connected in series with each other in one light emitting device. Accordingly, the light emitting device may have one or a plurality of light emitting cells, and when n light emitting cells are disposed in one light emitting device, the light emitting device may be driven at a driving voltage of n times. For example, when the driving voltage of one light emitting cell is 3V and two light emitting cells are arranged in one light emitting device, each light emitting device may be driven at a driving voltage of 6V. Alternatively, when the driving voltage of one light emitting cell is 3V and three light emitting cells are arranged in one light emitting device, each light emitting device may be driven at a driving voltage of 9V. The number of light emitting cells arranged in the light emitting device may be one or two to five.

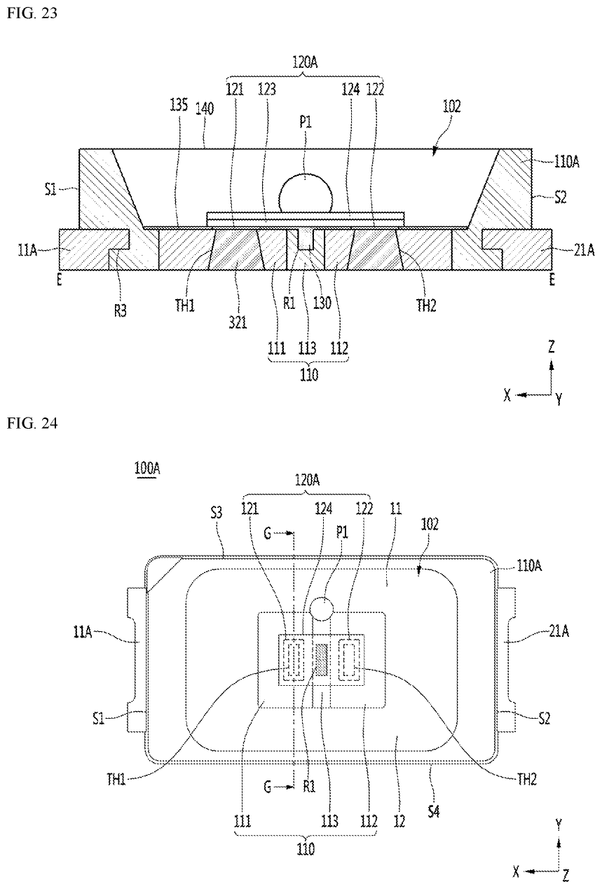

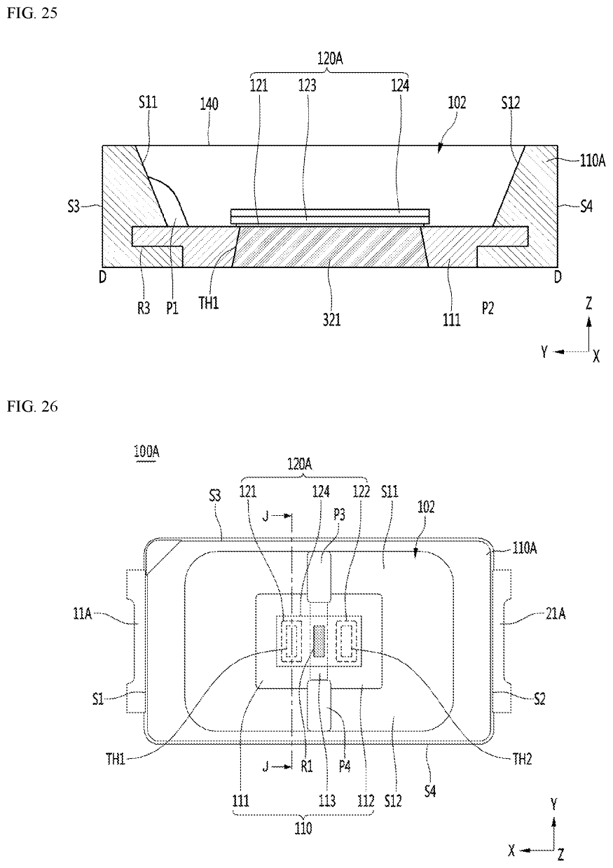

Referring to FIGS. 16, 22, 23, 29, and 30, the first resin 130 may be disposed between the body 113 and the light emitting device 120A and may include an adhesive material. The first resin 130 may be adhered to the light emitting device 120A and the body 113 and the first bonding portion 121 and the second bonding portion 122 of the light emitting device 120A.

Referring to FIGS. 15 and 16, the light emitting device package 100A may include a first upper recess R1. The first upper recess R1 may be provided in one or a plurality in the body 113 or the upper portion of the body 113. The first upper recess R1 may be provided in the body 113 between the first through hole TH1 and the second through hole TH2. The first upper recess R1 may be provided in the body 113 between the first frame 111 and the second frame 112. The first upper recess R1 may be recessed in a direction of a lower surface on an upper surface of the body 113.

The depth of the first upper recess R1 may be smaller than the depth of the first through hole TH1 or the depth of the second through hole TH2. The depth of the first upper recess R1 may be determined in consideration of the adhesive force of the first resin 130. In addition, the depth of the first upper recess R1 may be determined by considering the stable strength of the body 113 and/or by the heat emitting by the light emitting device 120A to prevent cracking of the light emitting device package 100A.

The depth of the first upper recess R1 may be in the range of 100 micrometers or less, for example, in the range of 15 to 100 micrometers, and in the case where the depth of the first upper recess R1 is smaller than the range, the resin supporting force may be lowered, and when it is greater than the range, the rigidity of the body 113 may be degraded and the improvement of the supporting force may be insignificant and may cause light leakage through the body 113.

The width of the first upper recess R1 in the first direction may be smaller than an interval between the first bonding portion 121 and the second bonding portion 122 in the X direction of the light emitting device 120A, and may be provided in the range of 140 micrometers or more, for example, in the range of 140 to 160 micrometers.

The length of the first upper recess R1 in the second direction is smaller than the length of the light emitting device 120A in the second direction, so that the first resin 130 may be function as a supporting protrusion under the light emitting device 120A. The length of the first upper recess R1 in the second direction may be longer than the length of the second light emitting device 120A to strengthen the adhesive force in the second direction with respect to the light emitting device 120A.

The depth of the first upper recess R1 and the width in the first direction may affect the forming position and the fixing force of the first resin 130. The depth and width of the first upper recess R1 may be determined so that sufficient fixing force may be provided by the first resin 130 disposed between the body 113 and the light emitting device 120A.

A top view shape of the first upper recess R1 may be a polygonal shape, for example, a triangular, rectangular, or pentagonal shape. As another example, the top view shape of the first upper recess R1 may be circular or elliptical. The first upper recess R1 may be provided in a shape capable of receiving and supporting the first resin 130 before curing. A cross-section shape of the first upper recess R1 may be a polygonal or a curved shape, for example, a triangular shape, a square shape, or a hemispherical shape. The structure of the first upper recess R1 may be provided in a structure in which the supporting force does not decrease while reducing the influence on the body 113.

The first upper recess R1 may have an upper width greater than a lower width in the first direction. The first upper recess R1 may have the upper width greater than the lower width in the first and second directions. The first upper recess R1 may have a shape in which the upper width is wider than the lower width in the first direction. Since the first upper recess R1 has a polygonal shape and the upper width is wider than the lower width, the first upper recess R1 may be provided as an inclined surface. Accordingly, the first resin 130 may be guided and supported in the first upper recess R1.

The body 113 may include projections P1 and P2 that protrudes further from the bottom of the cavity 102 than the bottom of the cavity 102. The cavity 102 may include a first projection P1 and a second projection P2. The first inner side surface S11 may include the first projection P1. The second inner side surface S12 may include the second projection P2. The projections P1 and P2 may be disposed to correspond to at least one of the side surfaces of the light emitting device 120A in the second direction, or may correspond to the side surfaces of the second direction.

The first projection P1 may be disposed on the body 113 and the first inner surface S11. The first projection P1 may be disposed on a boundary region between the body 113 and the first inner side surface S11. The second projection P2 may be disposed on the body 113 and the second inner side surface S12. The second projection P2 may be disposed on a boundary region between the body 113 and the second inner side surface S12. The first and second projections P1 and P2 may overlap the body 113 between the first frame 111 and the second frame 112 in a vertical direction Z. The first and second projections P1 and P2 may be formed on both ends of the body 113 and the first and second frames 111 and 112 at the bottom of the cavity 102. Since the first and second protrusions 11 and 12 are formed on the body 113 and the first and second frames 111 and 112, the rigidity of the body 113 between the first and second frames 111 and 112 may be strengthened. Therefore, the breaking strength of the light emitting device package 100A may be improved.

The first projection P1 may protrude toward the direction of the center of the cavity 102 or the direction of the light emitting device 120A from the first inner side surface S11. The first projection P1 may be adjacent to the first side surface of the light emitting device 120A and may be spaced apart from the first side surface of the light emitting device 120A. The second projection P2 may protrude toward the direction of the center of the cavity 102 or the light emitting device 120A from the second inner side surface S12. The second projection P2 may be adjacent to the second side surface of the light emitting device 120A and may be spaced apart from the second side surface of the light emitting device 120A. The first and second side surfaces of the light emitting device 120A may be opposite sides.

The distance between the first projection P1 and the first side surface of the light emitting device 120A may be smaller than the minimum distance between the first inner surface S11 and the first side surface of the light emitting device 120A. The distance between the second projection P2 and the first side surface of the light emitting device 120A may be smaller than the minimum distance between the second inner side surface S12 and the second side surface of the light emitting device 120A. The first and second projections P1 and P2 protrude to correspond to the first and second side surfaces opposite to each other of the light emitting device 120A, and are disposed on the body 113 and the first and second frames 111 and 112. By being formed in, the rigidity of the body 113 between the first and second frames 111 and 112 may be strengthened. Therefore, the breaking strength of the light emitting device package 100A may be improved.

The projections P1 and P2 face two opposite sides from each other in the light emitting device 120A in the second direction, and may be contacted the reflective portions 110A having the first and second frames 111 and 112 and the cavity 102. The projections P1 and P2 may be formed of or integrally formed with the same material as the body 113 and the reflective portion 110A.

The distance m2 between the first and second projections P1 and P2 may be smaller than the linear distance m1 between the first and second inner side surfaces S11 and S12. The straight line distance m1 between the first and second inner side surfaces S11 and S12 It may be a minimum distance in the second direction Y from the bottom of the cavity 102 in the region except for the first and second projections P1 and P2. The straight line distance m1 between the first and second inner side surfaces S11 and S12 may be greater than the length in the second direction of the light emitting device 120A.

A bottom width of the first projection P1 may be smaller than the minimum distance between the first light emitting device 120A and the first inner surface S11 in the second direction. A bottom width of the second projection P2 may be smaller than a minimum distance between the first light emitting device 120A and the second inner side surface S12 in the second direction.

The bottom width k2 of the first projection P1 may be greater than a width k1 of the upper surface of the body 113 between the first and second frames 111 and 112 in the first direction. A bottom width of the second projection P2 may be greater than the width k1 of the upper surface of the body 113 between the first and second frames 111 and 112 in the second direction. Accordingly, the first and second projections P1 and P2 may contact the upper surface of the body 113 and the upper surfaces of the first and second frames 111 and 112. Since the first and second protrusions 11 and 12 are in contact with the upper surfaces of the body 113 and the first and second frames 111 and 112, a rigidity of the body 113 disposed between the first and second frames 111 and 112 may be strengthened. Therefore, the breaking strength of the light emitting device package 100A may be improved.

A width in the second direction at the bottom of the projections P1 and P2 may be provided at least 30 micrometers or more to secure a contact area between the body 113 and the frames 111 and 112. The distance between the projections P1 and P2 and the light emitting device 120A may be spaced at least 50 micrometers or more, thereby reducing interference when mounting the light emitting device 120A and reducing the influence of light distribution.

The body 113 disposed between the first and second frames 111 and 112 may have the width of the upper surface and a width of the lower surface thereof. As another example, the width of the upper surface of the body 113 may be larger than the width of the lower surface thereof. As another example, the body 113 may have an upper surface width smaller than a lower surface width.

The first and second projections P1 and P2 and the body 113 may be formed of the same material. In this case, the first and second projections P1 and P2 may be integrally formed on the body 113. As another example, the first and second projections P1 and P2 and the body 113 may be different resin materials. In this case, bottom surfaces of the first and second projections P1 and P2 may be in contact with an upper surface of the body 113 with an interface. The first and second projections P1 and P2 may strengthen a strength of the body 113 between the first and second frames 111 and 112 when the reflective portion 110A and the body 113 are integrally formed of the same material.

Here, in the bottom of the first projection P1, an area of the bottom of the first projection P1 overlapping with the upper surface of the body 113 in the vertical direction may be larger than an area of a region overlapping with the upper surface of the first frame 111 in the vertical direction. In the bottom of the first projection P1, the area of the bottom of the first projection P1 overlapping the upper surface of the body 113 in the vertical direction may be larger than an area of the region overlapping the upper surface of the second frame 112 in the vertical direction. In the bottom of the second projection P2, an area of the bottom of the second projection P2 overlapping with the upper surface of the body 113 in the vertical direction may be greater than the area of the region overlapping with the top surface of the first frame 111 in the vertical direction. In the bottom of the second projection P2, the area of the bottom of the second projection P2 overlapping the upper surface of the body 113 in the vertical direction may be larger than an area of the region overlapping the upper surface of the second frame 112 in the vertical direction. Accordingly, the first and second projections P1 and P2 have an increased contact area between the body 113 and the first and second inner side surfaces S11 and S12 and the first and second frames 111 and 112, and may be supported by the first and second frames 111 and 112 to enhance the center-side rigidity of the light emitting device package.

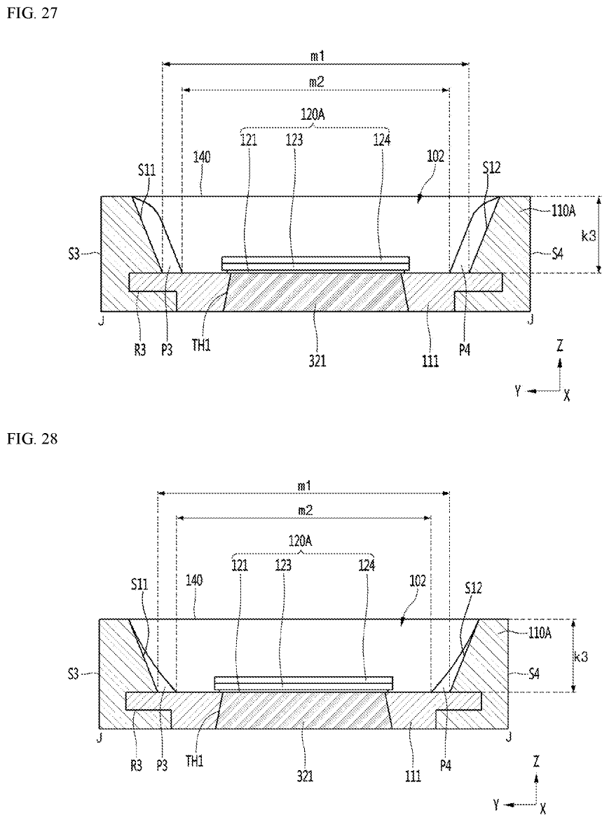

As shown in FIG. 18, a height k4 of the first and second projections P1 and P2 may be less than or equal to a depth k3 of the cavity 102 based on a bottom of the cavity 102 or the upper surface of the frames 111 and 112. Here, the depth of the cavity 102 is a straight line distance from the upper surface of the frames 111 and 112 to the upper surface of the reflective portion 110A. The height k4 of the first and second projections P1 and P2 may be in a range of 30% to 100% of the depth k3 of the cavity 102, and when smaller than the range, the bearing force may decrease. The height k4 of the first and second projections P1 and P2 is lower than the height of the reflective portion 110A (that is, a3) or equal to the height k3 of the reflective portion 110A as shown in FIGS. 27 and 28.

As shown in FIG. 18, the inner surface on the side cross-sections of the first and second projections P1 and P2 convexly protrudes toward the light emitting device 120A from the inclined surfaces of the first and second inner surfaces S11 and S12, and may increase the overlapping area with the bottom of the cavity 102. Accordingly, the breaking strength of the package may be improved by the first and second projections P1 and P2. As another example, as shown in FIG. 5, the inner side surfaces of the first and second projections P1 and P2 may be provided to be inclined to the bottom of the cavity 102 and may reflect light emitted from the light emitting device 120A. The inclined angles of the first and second projections P1 and P2 may be greater than the inclined angles of the first and second inner surfaces S11 and S12 based on the bottom of the cavity 102. Accordingly, the light incident from the light emitting device 120A may be reflected in the upward direction, and the breaking strength of the package may be increased.

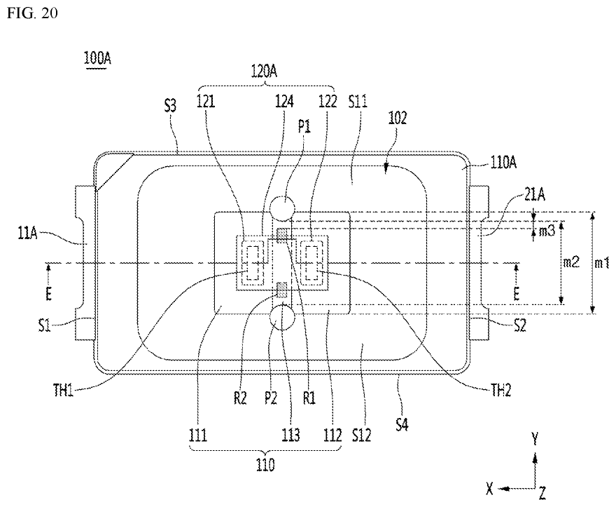

The distance m3 between the first upper recess R1 and the first and second projections P1 and P2 may be greater than a distance between the first and second projections P1 and P2 and the light emitting device 120A. As shown in FIG. 15, when the first upper recess R1 does not protrude outward from the region of the light emitting device 120A, the distance m3 may have the above relationship. Since the first and second projections P1 and P2 enhance the strength of both ends of the body 113, the length of the first upper recess R1 in the Y direction may be longer. Even if two or more upper recesses R1 are arrange positioned as shown in FIG. 20, the breaking strength of a package may be prevented from being lowered. As shown in FIG. 20, the minimum distance m3 between the two recesses R1 and R2 and the first and second projections P1 and P2 may be less than a distance between the light emitting device 120A and the first and second projections P1 and P2 and the light emitting device. As shown in FIG. 20, when a portion of the recesses R1 and R2 protrude outside a region of the light emitting device 120A, the distance m3 may have the above relationship. As shown in FIG. 20, the first and second projections P1 and P2 are disposed closer to the recesses R1 and R2 than the light emitting device 120A, so that the strength of the body 113 may be supported by the recesses R1 and R2.

Referring to FIGS. 16 to 18, the light emitting device package 100A according to the present invention may include at least two through holes. The through hole may include, for example, a first through hole TH1 and a second through hole TH2. Each of the first and second frames 111 and 112 may include first and second through holes TH1 and TH2.

The first and second through holes TH1 and TH2 may be provided in one or plural in the first and second frames 111 and 112, and may be provided through the upper and lower surfaces of each frame in the Z direction. By exposing the first and second bonding portions 121 and 122 through the first and second through holes TH1 and TH2, a conductive material filled in the first and second through holes TH1 and TH2 is be provided through electrical path and heat dissipation path.

As shown in FIG. 16, the width W1 of the upper regions of the first and second through holes TH1 and TH2 in the X direction may be provided to be smaller than or equal to the width of the first and second bonding portions 121 and 122. The widths of the first and second through holes TH1 and TH2 in the X direction may be the same or different from each other. Widths of the first and second bonding portions 121 and 122 in the X direction may be the same or different from each other.

The width W1 of the upper region of the first and second through holes TH1 and TH2 in the X direction may be equal to or smaller than the width W2 of the lower region. Since the width W1 of the upper region of the first and second through holes TH1 and TH2 is equal to or narrower than the width W2 of the lower region, it is possible to prevent the rigidity of the frames 111 and 112 from being lowered and may provide in an electrical path.

The length of the upper regions of the first and second through holes TH1 and TH2 in the Y direction may be smaller than or equal to the length of the first and second bonding portions 121 and 122. The lengths of the first and second through holes TH1 and TH2 in the Y direction may be different or the same from each other. The lengths of the first and second bonding portions 121 and 122 in the Y direction may be different or the same from each other.

The upper area of each of the through holes TH1 and TH2 may have a range of 30% or more, for example, 30% to 100% of an area of the lower surface of each of the bonding portions 121 and 122. In addition, the through holes TH1 and TH2 and the bonding portions 121 and 122 may have regions facing each other. Therefore, the first bonding portion 121 of the light emitting device 120A and the first frame 111 may be attached by a material provided in the first through hole TH1. The second bonding portion 122 of the light emitting device 120A and the second frame 112 may be attached by a material provided in the first through hole TH1.

The distance from the upper region of the second through hole TH2 to an end of the side surface of the second bonding portion 122 in the X direction may be provided at 40 micrometers or more, for example, in a range of 40 to 60 micrometers. When the distance is 40 micrometers or more, a process margin may be secured so that the second bonding portion 122 is not exposed from the bottom surface of the second through hole TH2. Also, when the distance is less than 60 micrometers, an area of the second bonding portion 122 exposed to the second through hole TH2 may be secured. Since the resistance of the second bonding portion 122 may be lowered, current input may be smoothly inputted into the second bonding portion 122 exposed by the second through hole TH2.

The first and second through holes TH1 and TH2 may have vertical side surfaces with the same width as the upper region and the lower region. Alternatively, the first and second through holes TH1 and TH2 may have a curved surface in which the width of the upper region is greater than the width of the lower region and the periphery surfaces of the through holes TH1 and TH2 are convex.

As another example, the through holes TH1 and TH2 may be provided in a shape in which the width of the X or Y direction gradually decreases from the lower region to the upper region. As another example, the periphery surface between the upper and lower regions of the first and second through holes TH1 and TH2 may be a plurality of inclined planes having different slopes, curved surfaces having curvatures, or curved surfaces having different curvatures.

An interval between the first through hole TH1 and the second through hole TH2 in the lower region of the first frame 111 and the second frame 112 may be provided, for example, in a range of 100 micrometers or more, for example, 100 micrometers to 600 micrometers. The distance between the through holes TH1 and TH2 may be a minimum distance for preventing an electrical short between the electrodes when the light emitting device package 100A may be mounted on a circuit board or a sub-mount. The interval between the through holes TH1 and TH2 may vary depending on the size of the light emitting device 120A.

As shown in FIGS. 15 and 16, the light emitting device package 100A according to the embodiment may include a first conductive layer 321 and a second conductive layer 322. The first conductive layer 321 may be spaced apart from the second conductive layer 322.

The first conductive layer 321 may be provided in the first through hole TH1. The first conductive layer 321 may be disposed under the first bonding portion 121. The width and length of the first conductive layer 321 in the X and Y directions may be provided smaller than the width and length of the first bonding portion 121.

The first bonding portion 121 may have a width in the X direction perpendicular to the Z direction in which the first through hole TH1 is formed. The width of the first bonding portion 121 may be larger than the width W2 of the first through hole TH1 in the X direction.

Each of the frames 111 and 112 and the bonding portions 121 and 122 may be combined by an intermetallic compound layer. The intermetallic compound may include at least one of CuₓSn_{y}, AgₓSn_{y}, and AuₓSn_{y}, and the x may satisfy a condition of 0<x<1, y=1−x, and x>y.

The conductive layer 321 may be provided as a conductive material in at least one or both of the through holes TH1 and TH2. The conductive layer 321 disposed in the first through hole TH1 is in contact with the lower surface of the first bonding portion 121 and the first frame 111 and may be electrically connected to the first bonding portion 121. The conductive layer 321 disposed in the second through hole TH2 is in contact with the lower surface of the second bonding portion 122 and the second frame 112 and may be electrically connected to the second bonding portion 122. The conductive layer 321 disposed in the first and second through holes TH1 and TH2 may be filled in a range of 30% or more, for example, 30% to 100% of the volume of the through holes TH1 and TH2. When it is smaller than the above range, the electrical reliability may be lowered. When it is larger than the above range, the bonding force with the circuit board may be lowered due to a protruding of the conductive layer. The material of the conductive layer 321 will be described with reference to FIG. 9.

The bonding portions 121 and 122 of the light emitting device 120A may be formed with an intermetallic compound (IMC) layer formed between the conductive layer 321 and the frames 111 and 112 by a forming process the conductive layer 321 or a heat treatment process after the conductive layer 321 is provide and the material constituting the conductive layer 321. The intermetallic compound layer will be referred to the description of the first embodiment.

An alloy layer may be formed between the conductive layer 321 and the frames 111 and 112. The alloy layer may be formed on the surfaces of the through holes TH1 and TH2 of the frames 111 and 112. The alloy layer may include the intermetallic compound layer having at least one selected from the group consisting of AgSn, CuSn, AuSn, and the like.

Here, an alloy layer may be formed by bonding between the material constituting the conductive layer 321 and the metal of the frames 111 and 112. Accordingly, the conductive layer 321 and the frames 111 and 112 may be physically and electrically bonded stably. The alloy layer may include at least one intermetallic compound layer selected from the group including AgSn, CuSn, AuSn, and the like. The intermetallic compound layer may be formed by combining a first material and a second material, the first material may be provided from the conductive layer 321, and the second material may be provided the bonding portions 121 and 122 or the frames 111 and 112. The intermetallic compound layer may have a higher melting point than other bonding materials.

The depths of the first and second through holes TH1 and TH2 may be equal to the thicknesses of the first and second frames 111 and 112. The depth of the first and second through holes TH1 and TH2 may be equal to the thickness of the body 113. For example, the depth of the first through hole TH1 may be provided in a range of 180 micrometers or more, for example, 180 to 300 micrometers.

When the depth of the first upper recess R1 is t1 and the depths of the through holes TH1 and TH2 are t2, for example, the thickness difference of the depth t2−t1 may be selected at least 100 micrometers or more. This is to consider the thickness of the injection process that may provide a crack free of the body. According to an embodiment, a ratio t2/t1 of t1 depth to t2 depth may be provided as 2 to 10. For example, when the depth of t2 is provided at 200 micrometers, the depth of t1 may be provided at 20 micrometers to 100 micrometers.

The light emitting device package 100A according to the embodiment of the present invention may include a molding member 140. The molding member 140 will be referred to the description of the first embodiment.

When the light emitting device package 100A is bonded to a main board through a reflow process, re-melting does not occur, and thus, electrical connection and physical bonding force are not degraded. In addition, the package body 110 does not need to be exposed to high temperature in the process of manufacturing the light emitting device package. Therefore, the package body 110 may be exposed to high temperature to prevent damage or discoloration. Accordingly, the selection range for the material constituting the body 113 may be widened.

The body 113 may include a first upper recess R1, and the projections P1 and P2 may be in contact with the body 113 and the frames 111 and 112. Accordingly, the strength of the body 113 between the frames 111 and 112 may be prevented from being lowered. It may also improve the breaking strength in the center region of the package.

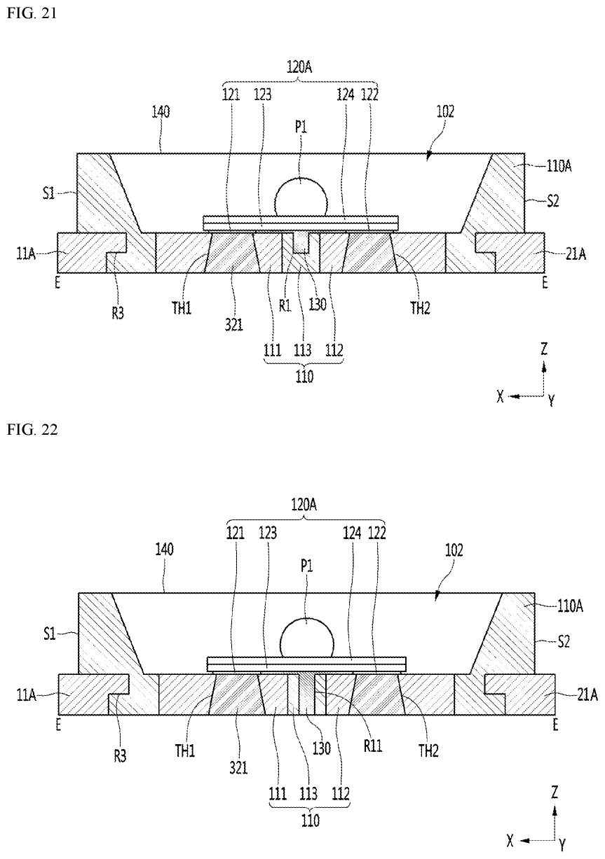

FIGS. 20 and 21 are plan views and E-E side cross-sectional views showing modified examples of the light emitting device package according to the embodiment.

Referring to FIGS. 20 and 21, the light emitting device package 100A includes first and second projections P1 and P2. The first and second projections P1 and P2 may be disposed at both ends of the body 113 disposed between the plurality of frames 111 and 112. The first and second projections P1 and P2 may contact both ends of the body 113 and upper surfaces of the plurality of frames 111 and 112. The first and second projections P1 and P2 may improve the breaking strength in the third direction of the light emitting device package 100A. An interval between the first projection P1 and the second projection P2 may be longer than the length of the light emitting device 120A in the second direction.

The body 113 disposed between the plurality of frames 111 and 112 includes a plurality of upper recesses R1 and R2. A portion of each of the plurality of upper recesses R1 and R2 may overlap the light emitting device 120A in the third direction or the vertical direction. A portion of the plurality of upper recesses R1 and R2 partially overlaps the light emitting device 120A, so that the first resin 130 adhered between the body 113 and the light emitting device 120A may be introduced into the plurality of upper recesses R1 and R2 and combined as a support protrusion.

Among the plurality of upper recesses R1 and R2, the first upper recess R1 protrudes outward from the first side surface of the light emitting device 120A, and the second upper recess R2 may protrude outward from the second side surface opposite to the first side surface of the light emitting device 120A. The region overlapping the light emitting device 120A among the upper recesses R1 and R2 may have a length in a second direction of 100 micrometers or less, for example, in a range of 30 to 100 micrometers. Each of the upper recesses R1 and R2 overlaps the light emitting device 120A at least 30 micrometers or more, thereby providing a path through which the first resin 130 disposed below the light emitting device 120A flows, and it may be arranged smaller than the above range, to reduce the light loss. The first resin 130 may be exposed to the outside of the light emitting device 120A.

In the plurality of upper recesses R1 and R2, an overlapping area with the light emitting device 120A may be reduced compared to the structure of FIG. 15. Accordingly, it is possible to reduce the problem that light emitted to the lower surface of the light emitting device 120A passes through the upper recesses R1 and R2 to the bottom of the body, and prevents the first resin 130 from leaking out and an inflow of the first resin 130 may be guided. The first resin 130 is attached and cured between the body 113 and the lower surface of the light emitting device 120A, and between the light emitting device 120A and the frames 111 and 112, and the upper recess R1 and R2 may strengthen the supporting force of the first resin 130 introduced and may function as a dam.

The minimum interval between the plurality of upper recesses R1 and R2 may be smaller than the length of the second direction of the light emitting device 120A, and the maximum interval may be greater than the length of the second direction of the light emitting device 120A. Accordingly, the first resin 130 under the light emitting device 120A may easily flow into the recesses R1 and R2 and may reduce light loss.

Each of the plurality of upper recesses R1 and R2 may have a top view shape in a triangular, square, or pentagonal shape. As another example, the upper recesses R1 and R2 may have a top view shape in a circular shape or an ellipse shape, and may provide a shape capable of guiding the first resin 130. The upper recesses R1 and R2 may have a polygonal shape or a curved shape in a side cross section, for example, a triangular shape, a square shape, or a hemispherical shape. The structures of the upper recesses R1 and R2 may be provided in a structure in which the supporting force does not decrease while reducing the influence on the body 113.

The upper recesses R1 and R2 may have an upper width wider than a lower width in a first direction. The upper recesses R1 and R2 may have an upper width wider than a lower width in the first and second directions. The upper recesses R1 and R2 may have a shape in which an upper width is wider than a lower width in the first direction. The upper recesses R1 and R2 may have a polygonal shape and have the upper width wider than the lower width, so that the upper recesses R1 and R2 may be provided as inclined surfaces. Accordingly, the first resin 130 may be guided and supported in the upper recesses R1 and R2.

The maximum interval between the plurality of recesses R1 and R2 may be smaller than the minimum interval m2 between the plurality of projections P1 and P2. Each of the plurality of recesses R1 and R2 may be adjacent to the projections P1 and P2 at a predetermined distance m3 and may overlap each other in the second direction. Accordingly, the projections P1 and P2 may prevent the rigidity of the body 113 from which the rigidity is reduced by each of the upper recesses R1 and R2. An interval m3 between the first upper recess R1 and the first projection P1 may be smaller than an interval between the first upper recess R1 and the second recess R2. The interval m3 between the first upper recess R1 and the first projection P1 may be less than the minimum interval between the first upper recess R1 and the first inner side surface S11 of the cavity 102. The interval m3 between the second recess R2 and the second projection P2 may be smaller than an interval between the first upper recess R1 and the second recess R2. The distance m3 between the second recess R2 and the second projection P2 may be smaller than the minimum interval between the second recess R2 and the second inner side surface S12 of the cavity 102. Since the first and second recesses R1 and R2 are disposed adjacent to the projections P1 and P2, the rigidity of the body 113 in the first and second directions may be strengthened.

The bottom width of the projections P1 and P2 in the first direction may be greater than a width of the upper surface of the body 113, and the width of the upper surface of the body 113 may be greater than a width of the upper surfaces of the upper recesses R1 and R2. The projections P1 and P2 disposed on both sides of the body 113 in the second direction may correspond each other or face each other, or their bottom centers may be arranged on a straight line such as the center of the upper recesses R1 and R2.

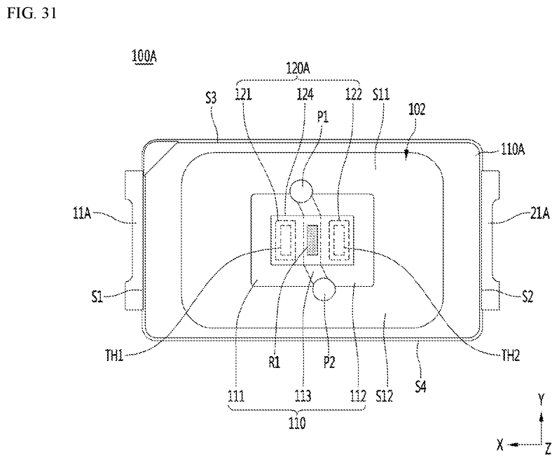

As another example, as shown in FIG. 31, the projections P1 and P2 may be disposed in opposite directions of the body 113 and may be disposed to be offset from each other, or the center of the upper recess R1 and the center of the projections P1 and P2 may be arranged the same centers on different straight lines. The projections P1 and P2 may be displaced by the structures of the frames 111 and 112. For example, the first projection P1 is disposed on the body 113 closer to the first through hole TH1 than the second through hole TH2, and the second projection P2 ma be disposed on the body 113 closer to the second through hole TH2 than the first through hole TH1. The first upper recess R1 disclosed in FIG. 31 may be disposed in one or a plurality.

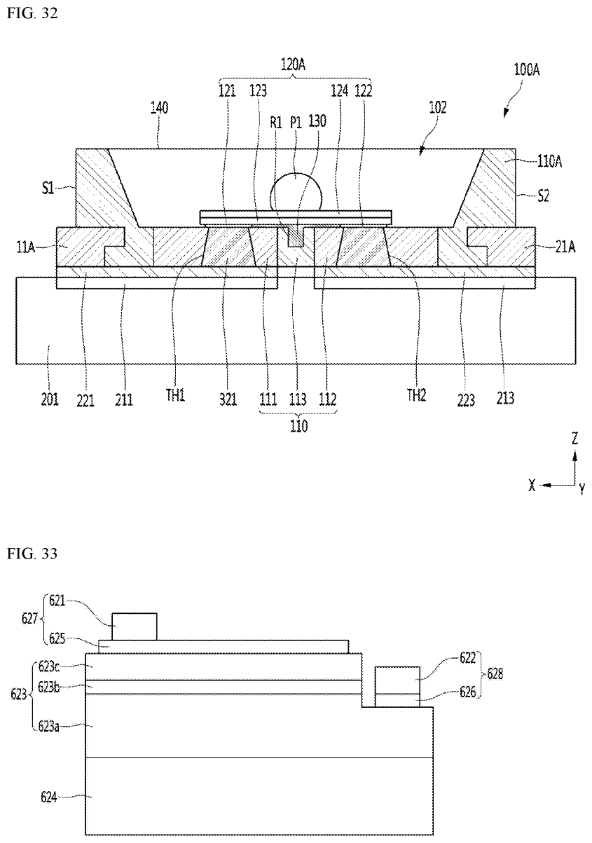

Referring to FIG. 32, the light emitting device package may include through holes TH1 and TH2 in at least one or both of the frames 111 and 112. One or a plurality of openings R11 may be disposed in the body 113 between the frames 111 and 112. The opening R11 may be disposed between the first and second through holes TH1 and TH2. The opening R11 may be provided between the first projection P1 and the second projection P2. The opening R11 may penetrate from the upper surface of the body 113 to the lower surface. The opening R11 may be disposed under the light emitting device 120A. The opening R11 may be provided to overlap the light emitting device 120A in the third direction. As shown in FIGS. 20 and 21, a plurality of openings R11 may be disposed, at least one of the plurality of openings may pass through the body 113, and the other opening may not pass through the body 113. The location of the opening R11 may be disposed under the center of the light emitting device, and may be disposed to overlap at least a portion below both sides.

The first resin 130 may be disposed in the opening R11. The first resin 130 may be disposed between the light emitting device 120A and the body 113. The first resin 130 may be disposed between the first bonding portion 121 and the second bonding portion 122. For example, the first resin 130 may contact the side surface of the first bonding portion 121 and the side surface of the second bonding portion 122. When the first resin 130 is formed, the first resin 130 may be formed in the opening R11 after a support sheet is disposed on the bottom of the package body 110.

According to an embodiment of the present disclosure, the depth of the opening R11 may be equal to the thickness of the frames 111 and 112. A width in the first direction of the opening R11 may be smaller than a gap between the frames 111 and 112. The width of the opening R11 may be provided in the long axis direction of the light emitting device 120A. The width in the first direction of the opening R11 may be smaller than the upper width in the first direction of the through holes TH1 and TH2 or the maximum width in the first direction of the projections P1 and P2. The length of the opening R11 may be smaller or larger than the length in the long axis direction of the light emitting device 120A, for example, the length in the second direction. The opening R11 may be provided in a narrow width toward the lower direction.

In the light emitting device package according to the embodiment of the present invention, an opening R11 having a penetrating shape may be further disposed below the body 113 to strengthen the coupling with the body 113.

As shown in in FIG. 33, the second resin 135 may be disposed around an outer periphery of the light emitting device 120A. The second resin 135 may be adhered between the first and second frames 111 and 112 and an outer lower surface of the light emitting device 120A. The second resin 135 may reflect light incident from the light emitting device 120A. The thickness of the second resin 135 may be smaller than the distance between the light emitting device 120A and the frames 111 and 112. Accordingly, the second resin 135 may be minimized to rise up to the side of the light emitting device 120A.

The second resin 135 may be formed in a continuous ring shape or a frame shape along the periphery of the light emitting device 120A, or may be formed in a discontinuous ring shape or a frame shape spaced apart from the body 113.

For example, the second resin 135 may include at least one of an epoxy-based material, a silicon-based material, a hybrid material including an epoxy-based material and a silicon-based material. The second resin 135 may improve adhesion between the light emitting device 120A and the first and second frames 111 and 112.

As shown in FIGS. 34 and 35, the body 113 may have only one projection P1 disposed on a portion of the body 113. The projection P1 may be in contact with the upper surfaces of the frames 111 and 112 and the upper surface of the body 113 to strengthen the partial breaking strength of the partial region. In this case, the first upper recess R1 may be disposed in the center region or the outer region of the light emitting device 120A in the body 113. As another example, the first upper recess R1 may be disposed to partially protrude to the outside of the light emitting device in a region adjacent to the projection P1, thereby preventing the strength of the body 113 from being lowered. As another example, the first upper recess R1 may protrude in a region adjacent to the second inner side surface S12 opposite to the projection P1 and partially overlap the light emitting device 120A. By arranging the projections P1 singly, an alignment position of the light emitting device 120A may be set based on the projections P1.

Referring to FIGS. 26 to 28, the heights of the projections P3 and P4 may be the same as the height of the cavity. By increasing the heights of the projections P3 and P4, the support force between the reflective portion 110A and the bottom of the cavity 102 may be strengthened, thereby improving the breaking strength of the light emitting device package 100A. The projections P3 and P4 may be adhered to an upper surface of the body 113 and an upper surface of the frames 111 and 112, and disposed on the inner surfaces S11 and S12 of the cavity 102.

The maximum width of the projections P3 and P4 in the first direction may be greater than one time and three times less than the upper width of the first direction of the body 113. When the maximum width of the projections P3 and P4 in the first direction is smaller than the range, the improvement of the breaking strength may be insignificant. When the maximum width of the projections P3 and P4 is smaller than the range, the light distribution may affect and the breaking strength may limit. The first and second projections P1 and P2 are in contact with the upper surfaces of the body 113 and the first and second frames 111 and 112, and thus the rigidity of the body 113 between the first and second frames 111 and 112 may be strengthened. Therefore, the breaking strength of the light emitting device package 100A may be improved.

As shown in FIG. 27, the projections P3 and P4 may have the minimum interval in a second direction smaller than the minimum distance between the inner side surfaces of the cavity 102. The width of the second direction at the bottom of the projections P3 and P4 may be formed to be at least 30 micrometers or more, thereby ensuring a contact area between the body 113 and the frames. The projections P3 and P4 may be separated from the light emitting device 120A by at least 50 micrometers or more in the second direction, thereby reducing interference when the light emitting device 120A may mounted and reducing the influence of light distribution.

Inner surfaces of the projections P3 and P4 may be provided as inclined regions corresponding to the side surfaces of the light emitting device 120A. The inner surfaces of the projections P3 and P4 may be gradually further away from the light emitting device 120A with respect to the side surface of the light emitting device 120A. Inner surfaces of the projections P3 and P4 may improve light extraction efficiency. The inner surfaces of the projections P3 and P4 may increase the contact area with the molding member 140. Here, the projections P3 and P4 may include a columnar shape, and the projections P3 and P4 may be flat surfaces. The flat upper surfaces of the projections P3 and P4 may be provided as a step difference from the upper surface of the reflective portion 110A. This stepped surface may be provided as a structure on which other sheets or members may be mounted.

As shown in FIG. 28, the inner surfaces of the projections P3 and P4 may gradually widened as a distance from the light emitting device 120A to the upper surface with respect to the side surface of the light emitting device 120A. The inner surfaces of the projections P3 and P4 may have a curved surface concave in the direction of the inner surfaces S11 and S12 of the cavity. The concave curved surface may be increased a contact area with the molding member 140. The projections P3 and P4 may be gradually widened further toward the upper surface with respect to the light emitting device 120A based on the side surface of the light emitting device 120A.

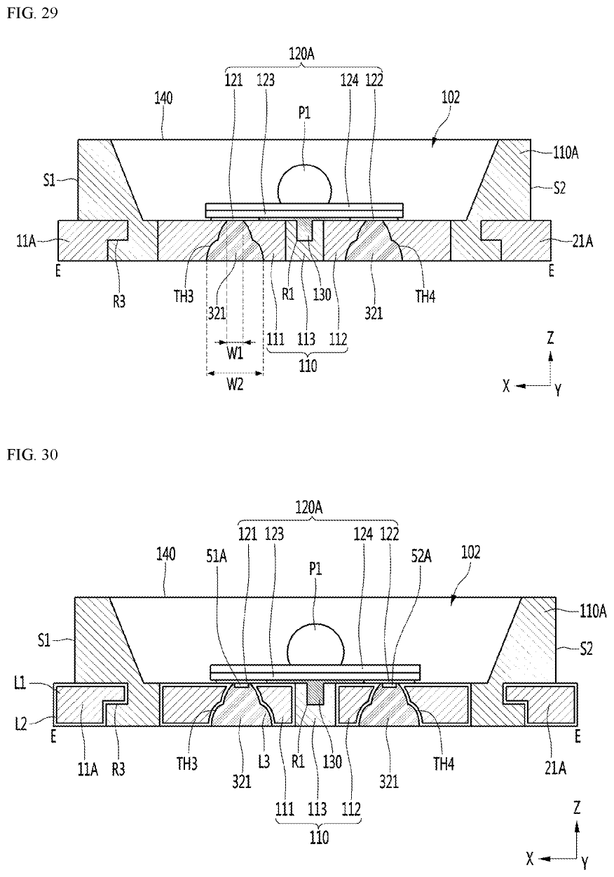

Referring to FIGS. 29 and 30, in the modified examples of the through holes of the light emitting device package, since side surfaces of the through holes TH3 and TH4 are formed in a curved surface, and the width or diameter thereof may gradually become smaller toward the upper direction. Or the side surfaces of the through holes TH3 and TH4 may be formed as curved surfaces having different curvatures, and a radius of curvature of the lower side thereof may be greater than a radius of curvature of the upper side thereof. The curved surface may be a curved surface that is convex outward from the center of the through holes TH3 and TH4. The curved surface having different curvatures in the through holes TH3 and TH4 may have one or more inflection points.

According to the embodiment of the present invention, the bonding portions 121 and 122 of the light emitting device 120A are disposed above the through holes TH3 and TH4 on the through holes TH3 and TH4, but a portion of the bonding portions 121 and 122 or a metal conductors 51A and 52A may be disposed in through holes TH3 and TH4 as shown in FIG. 30.

As shown in FIG. 30, the conductors 51A and 52A of the bonding portions 121 and 122 of the light emitting device 120A may be disposed less than 10% of the area of the lower surface of the light emitting device 120A. For example, the maximum areas of the conductors 51A and 52A of the bonding portions 121 and 122 may be provided smaller than the upper areas of the through holes TH3 and TH4. Accordingly, the conductors 51A and 52A of the bonding portions 121 and 122 of the light emitting device 120A may be inserted into the through holes TH3 and TH4. The lower surfaces of the conductors 51A and 52A of the bonding portions 121 and 122 of the light emitting device 120A may be lower than the upper surfaces of the body or the frames 111 and 112. The conductors 51A and 52A of the bonding portions 121 and 122 of the light emitting device 120A are disposed in the through holes TH3 and TH4, and may be coupled with the conductive layers 321 disposed in the through holes TH3 and TH4. The conductive layer 321 may contact around the conductors 51A and 52A of the bonding portions 121 and 122 of the light emitting device 120A to improve adhesion to the light emitting device 120A. In this case, power may be supplied to each bonding portion of the light emitting device 120A through the conductive layer 321. The conductors 51A and 52A of the light emitting device 120A according to the embodiment may be applied to other light emitting devices, but are not limited thereto. The conductors 51A and 52A may be provided as one conductor selected from a group including Al, Au, Ag, Pt, or an alloy thereof as a conductive body. The conductors 51A and 52A may be provided in a single layer or multiple layers.

The conductors 51A and 52A of the light emitting device 120A may be formed with an intermetallic compound (IMC) layer formed between the conductive layer 321 and the frames 111 and 112 by a forming process the conductive layer 321 or a heat treatment process after the conductive layer 321 is provide and the material constituting the conductive layer 321. The conductive layer 321 may include one material selected from the group consisting of Ag, Au, Pt, Sn, Cu, Zn, In, Bi, Ti, or an alloy thereof. However, the present invention is not limited thereto, and a material capable of securing a conductive function may be used as the conductive layer 321. For example, the conductive layer 321 may be formed using a conductive paste. The conductive paste may include a solder paste, a silver paste, or the like, and may include a multilayer or a single layer composed of a multilayer or an alloy composed of different materials. For example, the conductive layer 321 may include a SAC (Sn—Ag—Cu) material.

For example, an alloy layer may be formed by bonding between a material forming the conductive layer 321 and a metal of the frame. The alloy layer may include at least one intermetallic compound layer selected from the group including AgSn, CuSn, AuSn, and the like.

The frames 111 and 112 according to the embodiment include first and second metal layers L1 and L2, and the first metal layer L1 may include Cu, Ni, and Ti as a base layer, and may be formed as a single layer or a multilayer. The second metal layer L2 may include at least one of Au, Ni layers, and Ag layers. When the second metal layer L2 includes the Ni layer, since the Ni layer has a small change in thermal expansion, even when its size or arrangement position of the package body is changed by thermal expansion, and the position of the light emitting device disposed on the Ni layer may be stably fixed by the Ni layer. When the second metal layer L2 includes an Ag layer, the Ag layer may efficiently reflect light emitted from the light emitting device disposed on the Ag layer and improve luminous intensity. When the second metal layer L2 includes the Au layer, bonding strength with the bonding portions 121 and 122 of the light emitting device 120A may be improved and reflection efficiency may be improved.

The conductive layer 321 may be filled to 100% or less in the through holes TH1 and TH2, for example, to be filled in a range of 30% to 100%. When it is lower than the above range may be reduced, the conductive properties may be lowered.

An alloy layer L3 may be formed between the conductive layer 321 and the frames 111 and 112. The alloy layer L3 may be formed by bonding between the material constituting the conductive layer 321 and the second metal layer L2 of the frames 111 and 112. The alloy layer L3 may be formed on the surfaces of the through holes TH1 and TH2 of the frames 111 and 112. The alloy layer L3 may include an intermetallic compound layer having at least one selected from the group consisting of AgSn, CuSn, AuSn, and the like.

FIG. 32 is an example of a light source device or a light source module in which the light emitting device package of FIG. 16 is disposed on a circuit board. As an example, a light source device having a light emitting device package according to the first embodiment will be described as an example, and will be described below with reference to the description and drawings disclosed above. The light emitting device package may selectively apply the embodiment (s) disclosed above.

Referring to FIGS. 16 and 32, in the light source module according to the embodiment, one or more light emitting device packages 100A may be disposed on the circuit board 201.

The circuit board 201 may include a circuit member having pads 221 and 223. A power supply circuit for controlling the driving of the light emitting device 120A may be provided on the circuit board 201. Each of the frames 111 and 112 of the light emitting device package 100A may be connected to the pads 211 and 213 of the circuit board 201 through bonding layers 221 and 223. Accordingly, the light emitting device 120A of the light emitting device package 100A may receive power from each of the pads 211 and 213 of the circuit board 201. Each pad 211, 213 of the circuit board 201 may include, for example, at least one material or alloy selected from the group consisting of Ti, Cu, Ni, Au, Cr, Ta, Pt, Sn, Ag, P, Fe, Sn, Zn, and Al.

Each pad 221, 223 of the circuit board 201 may be disposed to overlap the frames 111 and 112 and the through holes TH1 and TH2. The bonding layers 221 and 223 may be provided between the pads 211 and 213 and the frames 111 and 112, respectively. The bonding layers 221 and 223 may be connected to the frames 111 and 112 and/or the conductive layers 321 of the through holes TH1 and TH2.

According to the light emitting device package according to the embodiment, the bonding portions 121 and 122 of the light emitting device 120A may be supplied with driving power through the conductive layers 321 disposed in the through holes TH1 and TH2 of the frames 111 and 112. The melting point of the conductive layer 321 disposed in the through holes TH1 and TH2 may be selected to have a higher value than the melting point of the general bonding material. The light emitting device package according to the embodiment does not have a re-melting phenomenon even when bonded to a main substrate through a reflow process, so that electrical connection and physical bonding force are not degraded. According to the light emitting device package according to the embodiment, the package body 110 and the body 113 need not be exposed to high temperatures in the process of manufacturing the light emitting device package. Therefore, according to the embodiment, the package body 110 and the body 113 may be exposed to high temperature to prevent damage or discoloration.

The light emitting device package disclosed in FIGS. 1 to 13 may be applied to the light emitting device package of FIGS. 15 to 17. Alternatively, each configuration of the first embodiment may be applied to the second embodiment, and each configuration of the second embodiment may be applied to the first embodiment.

Another example of a flip chip light emitting device applied to a light emitting device package according to an exemplary embodiment of the present invention will be described with reference to FIG. 33.

Referring to FIG. 33, the light emitting device may include a light emitting structure 623 disposed on a substrate 624. The light emitting structure 623 may include a first conductive semiconductor layer 623a, an active layer 623b, and a second conductive semiconductor layer 623c. The active layer 623b may be disposed between the first conductive semiconductor layer 623a and the second conductive semiconductor layer 623c. For example, the active layer 623b may be disposed on the first conductive semiconductor layer 623a, and the second conductive semiconductor layer 623c may be disposed on the active layer 623b. The first conductive semiconductor layer 623a may be provided as an n-type semiconductor layer, and the second conductive semiconductor layer 623c may be provided as a p-type semiconductor layer. Of course, according to another embodiment, the first conductive semiconductor layer 623a may be provided as a p-type semiconductor layer, and the second conductive semiconductor layer 623c may be provided as an n-type semiconductor layer.

The light emitting device can include a first electrode 627 and a second electrode 628. The first electrode 627 may include a first bonding portion 621 and a first branch electrode 625. The first electrode 627 may be electrically connected to the second conductive semiconductor layer 623c. The first branch electrode 625 may be branched from the first bonding portion 621. The first branch electrode 625 may include a plurality of branch electrodes branched from the first bonding portion 621. The second electrode 628 may include a second bonding portion 622 and a second branch electrode 626. The second electrode 628 may be electrically connected to the first conductive semiconductor layer 623a. The second branch electrode 626 may be branched from the second bonding portion 622. The second branch electrode 626 may include a plurality of branch electrodes branched from the second bonding portion 622.

The first branch electrode 625 and the second branch electrode 626 may be alternately arranged in a finger shape. Power supplied through the first bonding portion 621 and the second bonding portion 622 by the first branch electrode 625 and the second branch electrode 626 may be spread and provided to the entire light emitting structure 623.

A protective layer may be further provided on the light emitting structure 623. The protective layer may be provided on an upper surface of the light emitting structure 623. In addition, the protective layer may be provided on the side surface of the light emitting structure 623. The protective layer may be provided to expose the first bonding portion 621 and the second bonding portion 622. In addition, the protective layer may be selectively provided on the periphery and the lower surface of the substrate 624. For example, the protective layer may be provided as an insulating material. For example, the protective layer may be formed of at least one material selected from the group consisting of SiₓO_{y}, SiOₓN_{y}, SiₓN_{y}, and AlₓO_{y}.

In the light emitting device according to the embodiment, light generated in the active layer 623b may be emitted in six plane directions through the upper surface, lower surface, and four side surfaces of the light emitting device.

The sum of the areas of the first and second bonding portions 621 and 622 may be provided as 10% or less based on the area of the upper surface of the substrate 624. According to the light emitting device package according to the embodiment, the sum of the areas of the first and second bonding portions 621 and 622 to secure the light emitting area emitted from the light emitting device and to increase the light extraction efficiency may be set to 10% or less based on the upper surface area of the substrate 624. The first and second bonding portions 621 and 622 may be a conductor or a pad disclosed in the embodiment.

The sum of the areas of the first and second bonding portions 621 and 622 may be provided as 0.7% or more based on the area of the upper surface of the substrate 624. According to the light emitting device package according to the embodiment, the sum of the areas of the first and second bonding portions 621 and 622 to provide stable bonding force to the light emitting device to be mounted may be set to 0.7% or less based on the upper surface area of the substrate 624.

For example, the width of the first bonding portion 621 along the long axis of the light emitting device may be provided in several tens of micrometers. The width of the first bonding portion 621 may be provided, for example, from 70 micrometers to 90 micrometers. In addition, the area of the first bonding portion 621 may be provided in thousands of square micrometers.

In addition, the width along the long axis direction of the light emitting device of the second bonding portion 622 may be provided in several tens of micrometers. The width of the second bonding portion 622 may be provided, for example, from 70 micrometers to 90 micrometers. In addition, the area of the second bonding portion 622 may be provided in thousands of square micrometers. As such, as the areas of the first and second bonding portions 621 and 622 are provided to be small, the amount of light transmitted through the lower surface of the light emitting device may be increased.

The light emitting device of FIG. 33 has been described as a structure having one light emitting cell. When the light emitting cell includes the light emitting structure, the driving voltage of the light emitting device may be a voltage applied to one light emitting cell. Examples of the light emitting device disclosed in the embodiment may include a light emitting device having two or three or more light emitting cells. Accordingly, a high voltage light emitting device package may be provided.

Therefore, the light emitting device package according to the embodiment of the present invention does not deteriorate the electrical connection and the physical bonding force because the re-melting phenomenon does not occur even when bonded to the main substrate through a reflow process. There is an advantage.

On the other hand, one or more light emitting device packages according to an embodiment of the present invention may be disposed on the circuit board and applied to a light source device. In addition, the light source device may include a display device, a lighting device, a head lamp, or the like according to an industrial field.

As an example of the light source unit, a display device may include a bottom cover, a reflector disposed on the bottom cover, a light emitting module including a light emitting device that emits light, a light guide plate disposed in front of the reflector and guiding light emitted from the light emitting module forward, an optical sheet including prism sheets disposed in front of the light guide plate, a display panel disposed in front of the optical sheet, an image signal output circuit connected to the display panel to supply an image signal to the display panel, and a color filter disposed in front of the display panel. In this case, the bottom cover, the reflector, the light emitting module, the light guide plate, and the optical sheet may constitute a backlight unit. In addition, the display device may have a structure in which light emitting devices that emit red, green and blue light are disposed, respectively.

As still another example of the light source unit, the head lamp may include a light emitting module including a light emitting device package disposed on a substrate, a reflector for reflecting light emitted from the light emitting module in a predetermined direction, for example, forward, a lens for refracting light reflected by the reflector forward, and a shade for constructing a light distribution pattern desired by designer by blocking or reflecting a portion of the light that is reflected by the reflector to be directed to the lens.

As another example of the light source unit, the lighting device may include a cover, a light source module, a heat radiator, a power supply, an inner case, and a socket. In addition, the light source unit according to an embodiment may further include at least one of a member and a holder. The light source module may include a light emitting device package according to an embodiment.

Features, structures, effects, etc. described in the above embodiments are included in at least one embodiment, but are not necessarily limited to one embodiment. Furthermore, the features, structures, effects, and the like illustrated in the embodiments may be combined or modified with respect to other embodiments by those skilled in the art to which the embodiments belong. Therefore, it should be interpreted that the contents related to such a combination and modification are included in the scope of the embodiments.

Although the above description has been made with reference to the embodiments, these are only examples and are not intended to limit the embodiments, and those of ordinary skill in the art to which the embodiments pertain may have several examples that are not exemplified above without departing from the essential characteristics of the embodiments. It will be appreciated that eggplant modifications and applications are possible. For example, each component specifically shown in the embodiment may be modified. And differences related to such modifications and applications will have to be construed as being included in the scope of the embodiments set out in the appended claims.

1. A light-emitting device package comprising:
first and second frames spaced apart from each other;
a body supporting the first and second frames; and
a light emitting device disposed on the second frame,
wherein the body includes a lower surface, a first side surface, and a second side surface facing the first side surface,
wherein the first side surface and the second side surface face each other in a first direction,
wherein the first frame includes a first recess that is concave toward a direction of the second side surface from a first side portion adjacent to the first side surface,
wherein the second frame includes a second recess that is concave toward a direction of the first side surface from a second side portion adjacent to the second side surface;
wherein the first side portion of the first frame includes plurality of protrusions exposed to the first side surface of the body,
wherein the first recess is disposed between the protrusions of the first side portion,
wherein the second side portion of the second frame includes plurality of protrusions exposed to the second side surface of the body,
wherein the second recess is disposed between the protrusions of the second side portion,
wherein a first length of each of the first and second recesses in a second direction is longer than a width in the first direction,
wherein the second direction is a direction orthogonal to the first direction,
wherein the first length is greater than a second length in the second direction, which is an interval between the protrusions disposed in each of the first and second frames, and
wherein a ratio of the second length to the first length ranges from 0.3 to 0.6.

2. The light-emitting device package of claim 1,
wherein a width in the second direction of a region where the first and second recesses and the protrusion overlap in the first direction in each protrusion of the first and second frames has a range of 0.5 to 1 compared to the second length.

3. The light-emitting device package of claim 2,
wherein the body includes a cavity at an upper portion thereof, and
wherein the first and second recesses overlap with the body in a vertical direction and are spaced apart from a bottom of the cavity in the first direction.

4. The light-emitting device package of claim 1,
wherein a portion of the body is exposed on the first and second recesses, and
wherein a maximum length of each of the first and second recesses in the second direction is larger than an interval between two protrusions of each of the first and second frames.

5. The light-emitting device package of claim 4,
wherein each of the first and second recesses have a minimum length in the second direction greater than the width in the first direction.

6. The light-emitting device package of claim 5,
wherein a portion of the plurality of protrusions protruding from the first and second frames has a minimum width coupled to the body in the second direction and corresponds to the first and second recesses and smaller than an outer width of each protrusion.

7. The light-emitting device package of claim 4,
wherein the plurality of protrusions of the first frame has a stepped portion around an upper portion of the first recess, and
wherein the plurality of protrusions of the second frame has a stepped portion around an upper portion of the second recess.

8. The light-emitting device package of claim 7,
wherein the first and second frames are conductive frames,
wherein the light emitting device is disposed on any one of a vertical chip, a horizontal chip or a flip chip on the first and second frames,
wherein the body disposed between the first and second frame is disposed under the light emitting device and includes a recess or opening, and
wherein a reflective resin is disposed in the recess or the opening.

9. A light-emitting device package comprising:
first and second frames spaced apart from each other in a first direction;
a body disposed between the first and second frames;
a reflective portion disposed on the body and constituting a cavity; and
a light emitting device disposed in the cavity and including first and second bonding portions at a lower portion thereof;
wherein the body includes a projection,
wherein the projection is in contact with the first and second frames and the reflective portion and spaced apart from side surfaces of the light emitting device in the second direction,
wherein the second direction is a direction orthogonal to the first direction, and
wherein the projection and the body includes a resin material.

10. The light-emitting device package of claim 9,
wherein the projection is disposed on both inner surfaces of the cavity and include a plurality of projections facing the light emitting device.
wherein the projection has a height equal to or lower than a height of the reflective portion, and
wherein the projection protrudes in a direction of the light emitting device from the inner surfaces of the cavity.

11. The light-emitting device package of claim 10, wherein the light emitting device includes two side surfaces facing in the second direction, and each of the plurality of projections faces each of the side surfaces of the light emitting device.

12. The light-emitting device package of claim 10, wherein the projections and the reflective portion are formed of the same material.

13. The light-emitting device package of claim 10, wherein an upper surface of the projection is provided as a flat surface.

14. The light-emitting device package of claim 10, wherein a distance between the projections and a lower end of the side surface of the light emitting device is smaller than a distance between the projection and an upper end of the side surface of the light emitting device.

15. The light-emitting device package of claim 10, wherein a bottom width of the projection in the first direction is more than one and three times less than a width of the body.

16. The light-emitting device package of claim 10, comprising:
a first resin disposed between the body and the light emitting device; and
a recess disposed in the body and at least partially overlapping the light emitting device in a vertical direction.

17. The light-emitting device package of claim 16, comprising:
a first through hole disposed in the first frame and a second through hole disposed in the second frame,
wherein the first and second through holes overlap with the light emitting device in the vertical direction,
wherein the first through hole is disposed under the first bonding portion of the light emitting device,
wherein the second through hole is disposed under the second bonding portion of the light emitting device, and
wherein the first and second through holes include a conductive layer therein.

18. The light-emitting device package of claim 16, wherein a portion of the recess protrudes outwardly than a side surface of the light emitting device in the second direction.

19. The light-emitting device package of claim 16, wherein a minimum distance between the recess and the projection is smaller than a distance between the light emitting device and the projection.

20. A lighting module having the light emitting device package according to claim 1.
